(19) United States
(12) Patent Application Publication
(10) Pub. No.: US 2011/0305979 A1
(43) Pub. Date: Dec. 15, 2011

(54) RESIST TOP COAT COMPOSITION AND PATTERNING PROCESS

(75) Inventors: Yuji HARADA, Jyoetsu (JP); Taku MORISAWA, Jyoetsu (JP); Takeru WATANABE, Jyoetsu (JP); Yuki SUKA, Jyoetsu (JP)

(73) Assignee: SHIN-ETSU CHEMICAL CO., LTD., Tokyo (JP)

(21) Appl. No.: 13/116,853

(22) Filed: May 26, 2011

(30) Foreign Application Priority Data
Jun. 11, 2010 (JP) 2010-134433

(51) Int. Cl. G03F 1/00; C09D 127/12; C08K 5/06; G03F 7/20

(52) U.S. Cl. 430/5; 430/325; 524/544; 524/378

(57) ABSTRACT

The invention provides a resist top coat composition wherein the composition contains polymer (P1-1) with a weight-average molecular weight of 1,000 to 500,000, having at least repeating units represented by the following general formulae (1a), (1b-1), and (1c). There can be a resist top coat composition having excellent water repellent and water sliding properties with fewer development defects and with a good resist pattern profile after development, and a patterning process using this composition.

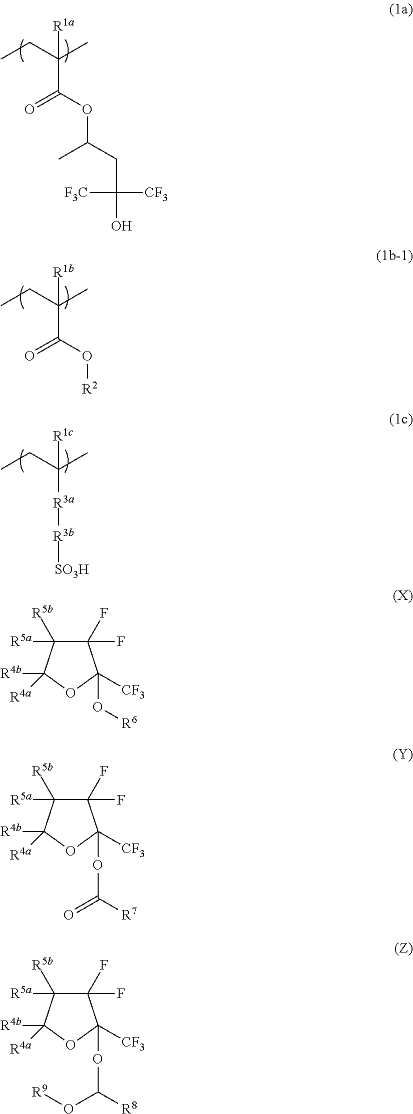

### BACKGROUND OF THE INVENTION

1. Field of the Invention

The present invention relates to a resist top coat composition to form a top coat on a photoresist film to be used in a photolithography for micro fabrication in a manufacturing process of a semiconductor element and the like (for example, an immersion photo lithography wherein exposure is conducted by inserting a liquid such as water between a projection lens and a substrate by using an ArF excimer laser having wavelength of 193 nm as a light source), and to a patterning process using the composition thereof.

2. Description of the Related Art

In recent years, as LSI progresses toward a higher integration and a further acceleration in speed, a miniaturization of a pattern rule is rapidly progressing. This trend is caused by a shift of an exposure light source toward a shorter wavelength; and for example, an actual utilization of a 65-nm node device is studied by shifting the wavelength toward a shorter wavelength even to an ArF excimer laser (193 nm) via an i-line of a mercury lamp (365 nm) and a KrF excimer laser (248 nm). In more recent years, a study of an ArF immersion lithography wherein exposure is conducted by impregnating water between a projection lens and a wafer has been started, so that a miniaturization to a level of 45 nm or lower becomes possible by combination of a lens having NA of 1.2 or more and a super-resolution technology (Proc. SPIE. Vol. 5040, p 724 (2003)).

In an ArF immersion exposure, there is a possibility that a water-soluble component in a resist film may be leached out into immersed water (leaching) and thereby there is a possibility to cause deformation and collapsing of a pattern. It is also pointed out that there is a possibility to induce a defect by minute water droplets remained after scanning. Accordingly, a method to suppress leaching-out of a resist component and a defect derived from water by arranging a top coat on a resist film (top coat process) is proposed in an ArF immersion lithography (see 2nd Immersion Work shop: Resist and Cover Material Investigation for Immersion Lithography (2003)).

In the case that a top coat process is used in an ArF immersion lithography, if an alkaline-soluble top coat composition is used, a top coat can be removed at the same time with development; and therefore, there is a great benefit in terms of cost and processing. Accordingly, development of a water-insoluble resist top coat composition by using an alkaline-soluble resin is being carrying out strenuously.

On the other hand, a method to suppress leaching-out of a resist component into water without using a top coat composition (top-coatless process) has been developed. In this method, an alkaline-soluble hydrophobic polymer is added to a resist in advance thereby localizing a hydrophobic compound on a resist surface upon forming a resist film. As a result, an effect similar to the case of using a top coat can be realized. The top-coatless process is advantageous costly because steps of forming and removing of a top coat are not necessary.

In any of a top coat and a top-coatless process, a scanning speed of about 300 to about 700 mm/second is requested to increase a throughput in an ArF immersion exposure. When conducting such a high speed scanning, a water droplet remains on a film surface after scanning if water repellency of a resist film or a top coat is insufficient; and thus there is a possibility to cause a defect by the water droplet. To avoid such a defect, it is necessary to improve water repellent and water sliding properties (especially receding contact angle) of a coating film.

To improve water repellent and water sliding properties of a resin, a method to introduce a fluorine atom into a polymer skeleton is known. For example, a copolymer of α-trifluoromethyl acrylate ester and a norbornene derivative (see Proc. SPIE. Vol. 4690, p 18 (2002)), or a fluorinated ring-closure polymer having a fluorine-containing alcohol unit on its side chain (see Proc. SPIE. Vol. 6519, 651905 (2007)) shows performance of excellent water repellent and water sliding properties. It is reported that the latter polymer shows further improvement in a water sliding property by protecting the fluorine-containing alcohol with an acid labile group.

Introduction of a fluorine atom into a polymer skeleton can cause remarkable improvement of water repellent and water sliding properties; but excessive introduction causes a new defect called a blob defect. This defect appears upon spin drying after development; and the defect occurs easily if a surface contact angle after development is large. Accordingly, the blob defect can be depressed by introducing a highly hydrophilic substituent group (such as a carboxylic group and a sulfo group) into a resin thereby decreasing a surface contact angle after development. However, a resin containing these groups cannot be applied to the high speed scanning as mentioned above because the resin decreases water repellent and water sliding properties remarkably. Accordingly, development of a composition, capable of depressing a blob defect while maintaining high water repellent and water sliding properties upon an immersion exposure, is wanted.

The composition as mentioned above is expected to be applicable not only to an ArF immersion lithography but also to a resist composition for mask blanks. It is pointed out that, because exposure of mask blanks is conducted under vacuum for a long time, an amine component in a resist may be adsorbed on a resist film surface upon the exposure, thereby likely causing sensitivity change and deformation. Accordingly, a method wherein a top coat is formed on a resist film to inhibit adsorption of an amine onto a resist film is proposed.

### SUMMARY OF THE INVENTION

The present invention was conducted in view of the problems mentioned above; and the invention has an object to provide a resist top coat composition having excellent water repellent and water sliding properties with fewer development defects and with a good resist pattern profile after development, and to provide a patterning process using this composition.

To solve the problems, according to the present invention, provided is a resist top coat composition wherein the composition contains polymer (P1-1) with a weight-average molecular weight of 1,000 to 500,000, having at least repeating units represented by the following general formulae (1a), (1b-1), and (1c).

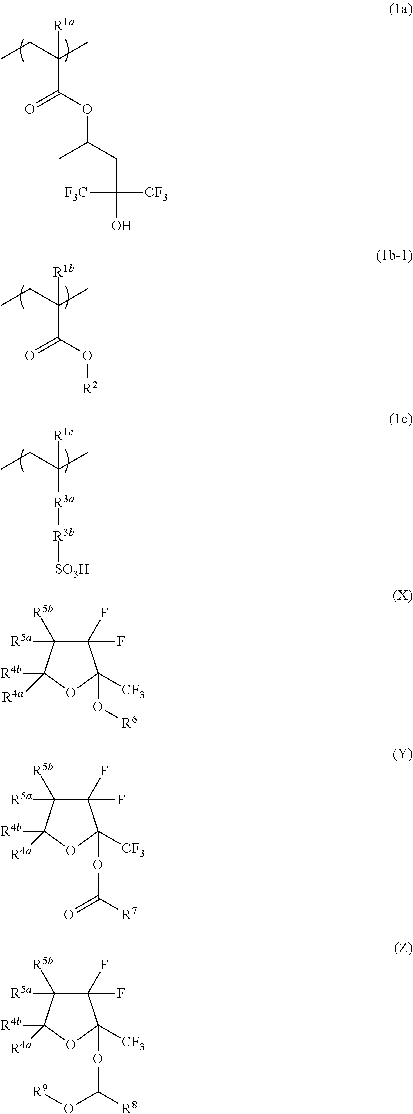

(Wherein, R^{1a} to R^{1c} represent a hydrogen atom or a methyl group. R² represents a group shown by any of the above general formulae (X), (Y), and (Z), and is connected to a —(C═O)—O— bond in repeating unit (1b-1) via any of R^{4a}, R^{4b}, R^{5a}, and R^{5b} in the general formulae (X), (Y), and (Z), wherein R^{4a}, R^{4b}, R^{5a}, and R^{5b} connected to the —(C═O)—O— bond represent a single bond or a linear, a branched, or a cyclic alkylene group having 1 to 15 carbon atoms. Each of R^{4a}, R^{4b}, R^{5a}, and R^{5b} not connected to the —(C═O)—O— bond in repeating unit (1b-1) represents independently any of a hydrogen atom, a hydroxyl group, a halogen atom, and a linear, a branched, and a cyclic monovalent organic group having 1 to 15 carbon atoms, wherein two of R^{4a}, R^{4b}, R^{5a} and R^{5b} may be bonded with each other to form a cyclic structure. R⁶, R⁷, and R⁹ represent a linear, a branched, or a cyclic alkyl group having 1 to 20 carbon atoms, wherein a part of their hydrogen atoms may be substituted with a halogen atom and a part of a methylene group may be substituted with an oxygen atom or a carbonyl group. R⁸ represents a hydrogen atom, or a linear, a branched, or a cyclic alkyl group having 1 to 20 carbon atoms, wherein a part of their hydrogen atoms may be substituted with a halogen atom and a part of a methylene group may be substituted with an oxygen atom or a carbonyl group. R⁸ and R⁹ may be bonded to form a cyclic structure. R^{3a} represents any of a single bond, —(C═O)—O—, and —(C═O)—NH—. R^{3b} represents a single bond, or a linear, a branched, or a cyclic alkylene group having 1 to 15 carbon atoms. In polymer (P1-1), if total mol of a monomer corresponding to each of the general formulae (1a), (1b-1), and (1c) is made U11, U12, and U13 and total mol of monomers corresponding to entire repeating units contained in polymer (P1-1) is made U1, they are in the following relationships:

0<U11/U1<1,

0<U12/U1<1,

0<U13/U1<1, and

0<(U11+U12+U13)/U1≦1).

In polymer (P1-1) described above, a repeating unit represented by the general formula (1a) not only contributes to solubility into an alkaline developer but also expresses performance of excellent water repellent and water sliding properties. Structure of a side chain in a repeating unit represented by the general formula (1b-1), such as number of carbon atoms, degree of branching, and number of fluorine atoms, can be easily controlled, so that a polymer showing necessary performance as a resist top coat composition with regard to water repellent and water sliding properties, lipophilicity, and decomposition properties by an acid and a hydrolysis can be manufactured. In addition to these repeating units, by combining them with a repeating unit having a sulfo group (general formula (1c)), a base polymer (polymer) for a resist top coat composition having an excellent pattern profile with fewer development defects can be obtained. The foregoing polymer (P1-1) has an excellent transparency to a radial ray with 200 nm or less of wavelength; and in addition, the polymer can be manufactured from an easily available and easy-to-use raw composition.

In the general formula (1c), R^{3a} and R^{3b} are preferably a single bond.

Accordingly, polymer (P1-1) may be made to contain a repeating unit whose R^{3a} and R^{3b} in the general formula (1c) are a single bond.

Further, the present invention provides a resist top coat composition wherein the composition contains polymer (P1-2) with a weight-average molecular weight of 1,000 to 500,000, having at least repeating units represented by the following general formulae (1a)′, (1b-2), and (1c)′.

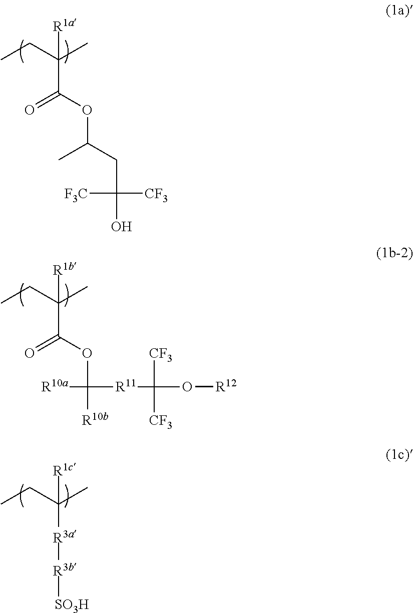

(Wherein, R^{1a′} to R^{1c′} represent a hydrogen atom or a methyl group. R^{10a} and R^{10b} represent a hydrogen atom, or a linear, a branched, or a cyclic monovalent hydrocarbon group having 1 to 15 carbon atoms, wherein R^{10a} and R^{10b} may be bonded with each other to form a non-aromatic ring having 3 to 8 carbon atoms. R¹¹ represents a single bond or a methylene group. R¹² represents any of a linear, a branched, or a cyclic monovalent hydrocarbon group or a fluorinated monovalent hydrocarbon group having 1 to 15 carbon atoms, and an acid labile group, wherein, in the case of a monovalent hydrocarbon group, a constituting —CH₂— group may be substituted with —O— or —C(═O)—. R^{3a′} represents any of a single bond, —(C═O)—O—, and —(C═O)—NH—. R^{3b′} represents a single bond, or a linear, a branched, or a cyclic alkylene group having 1 to 15 carbon atoms. In polymer (P1-2), if total mol of a monomer corresponding to each of the general formulae (1a)′, (1b-2), and (1c)′ is made U11′, U12′, and U13′ and total mol of monomers corresponding to entire repeating units contained in polymer (P1-2) is made U1′, they are in the following relationships:

0<U11′/U1′<1,

0<U12′/U1′<1,

0<U13′/U1′<1, and

0<(U11′+U12′+U13′)/U1′≦1).

In polymer (P1-2), a repeating unit represented by the general formula (1a)′ not only contributes to solubility in an alkaline developer but also expresses performance of excellent water repellent and water sliding properties. Structure of a side chain in the repeating unit represented by the general formula (1b-2), such as number of carbon atoms, degree of branching, and number of fluorine atoms, can be easily controlled, so that a polymer showing necessary performance as the resist top coat composition with regard to water repellent and water sliding properties, lipophilicity, and decomposition properties by an acid and a hydrolysis can be manufactured. In addition to these repeating units, by combining them with a repeating unit having a sulfo group (general formula (1c)′), a base polymer for a resist top coat composition having an excellent pattern profile with fewer development defects can be obtained. The foregoing polymer (P1-2) has an excellent transparency to a radial ray with 200 nm or less of wavelength; and in addition, the polymer can be manufactured from an easily available and easy-to-use raw composition.

In the general formula (1c)′, R^{3a′} and R^{3b′} are preferably a single bond.

Accordingly, polymer (P1-2) may be made to contain a repeating unit whose R^{3a′} and R^{3b′} in the general formula (1c)′ are a single bond.

In addition, it is preferable that the resist top coat composition further contain a solvent.

Accordingly, it is preferable that polymers (P1-1) and (P1-2) be used by dissolving them in a solvent.

In addition, it is preferable that the solvent be an ether compound having 8 to 12 carbon atoms.

Accordingly, a solvent not dissolving a resist layer is preferably used as the solvent; and the ether compound having 8 to 12 carbon atoms is preferable among the solvents not dissolving a resist layer.

The solvent is preferably di-n-butyl ether, di-isobutyl ether, di-isopentyl ether, di-n-pentyl ether, methyl cyclopentyl ether, methyl cyclohexyl ether, di-sec-butyl ether, di-sec-pentyl ether, di-t-amyl ether, and di-n-hexyl ether, wherein they may be used singly or in a combination of two or more of them.

The foregoing ether compounds may be mentioned as the solvent preferably used especially as the solvent for the resist top coat composition of the present invention.

It is preferable that the solvent contain, in addition to the foregoing ether compounds, one alcohol or a mixture of two or more of alcohols selected from any of 1-butyl alcohol, 2-butyl alcohol, isobutyl alcohol, tert-butyl alcohol, 1-pentanol, 2-pentanol, 3-pentanol, tert-amyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-diethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, and cyclohexanol.

A higher alcohol having 4 or more of carbon atoms as mentioned above does not dissolve a resist layer; and thus, it is preferable that a solvent used in the resist top coat composition of the present invention be made to contain, in addition to the ether compounds, a higher alcohol having 4 or more of carbon atoms.

In addition, the present invention provides a patterning process wherein the process includes at least (1) a step of forming a photoresist film over a substrate, (2) a step of forming a resist top coat on the photoresist film by using the resist top coat composition of the present invention, (3) a step of exposure, and (4) a step of developing by using a developer.

If a patterning process is conducted in a manner as mentioned above by forming a resist top coat on a photoresist film by using the resist top coat composition of the present invention, a lithography (especially an immersion lithography) giving fewer development defects and a good resist pattern profile after development can be realized.

Further, it is preferable that the foregoing step of exposure (3) be conducted by the immersion lithography wherein the exposure is conducted by using a high energy beam via a photo mask while inserting a liquid between a projection lens and the substrate. In addition, it is preferable that the liquid inserted between the projection lens and the substrate in the foregoing step of exposure (3) be water.

Accordingly, an immersion exposure, which is conducted by inserting a liquid between a resist top coat and a projection lens, is preferable in the step of exposure. When the exposure is conducted by an immersion exposure, the resist top coat composition of the present invention can act effectively so that a further finer resist pattern can be formed on a photoresist film. It is preferable to use water as the liquid to be inserted.

In the foregoing step of exposure (3), it is preferable to use a high energy beam having a wavelength in the range between 180 and 250 nm as an exposure light source.

In the foregoing step of exposure (3), especially in the case of the immersion exposure, it is preferable to use a high energy beam having a wavelength in the range between 180 and 250 nm as an exposure light source.

In the foregoing step of development (4), it is preferable that delamination of the resist top coat on the photoresist film be conducted at the same time as development by using an alkaline developer to form a resist pattern on the photoresist film.

Accordingly, in the step of development (4), if the resist top coat on the photoresist film is delaminated at the same time as development by using an alkaline developer to form a resist pattern on the photoresist film, the resist top coat can be delaminated further easily without installing a delaminating equipment additionally to a currently used equipment.

Further, the present invention provides a patterning process by lithography comprising steps of; forming a resist top coat by using a resist top coat composition on a photoresist layer formed over a mask blanks; conducting an exposure by an electron beam under vacuum; and developing, wherein the resist top coat composition of the present invention is used as the resist top coat composition.

Accordingly, the present invention is useful because a stability in a vacuum equipment after exposure can be improved by using the resist top coat composition of the present invention as the resist top coat composition in a patterning process by a lithography wherein, after a resist top coat is formed by a resist top coat composition on a photoresist layer formed on mask blanks, an exposure is conducted by an electron beam under vacuum, and then development is conducted.

According to the present invention, a resist top coat composition, containing a repeating unit ((1b-1) or (1b-2)) having a structure that a fluorinated cyclic hemiacetal or a fluorinated alcohol contained therein is protected, can be provided. The resist top coat composition has an excellent transparency in a radial ray of 200 nm or shorter; each performance such as water repellent and water sliding properties, lipophilicity, and decomposition properties by an acid and a hydrolysis can be controlled by selecting a structure of the resin; and the composition can be manufactured from an easily available and easy-to-use raw composition. In addition, the resist top coat composition of the present invention has a large receding contact angle so that leaching of a resist component may be suppressed; and on top of that, an immersion lithography with fewer development defects and with an excellent resist pattern profile after development can be realized.

### DETAILED DESCRIPTION OF THE PREFERRED EMBODIMENTS

As mentioned above, a resist top coat composition having excellent water repellent and water sliding properties, fewer development defects, and an excellent resist pattern profile after development has been wanted.

Inventors of the present invention carried out an investigation extensively to achieve the foregoing object, and as a result, they found that a polymer, having a structure that a fluorinated cyclic hemiacetal was protected (following general formula (1b-1)) or a structure that a fluorinated alcohol was protected (following general formula (1b-2)), showed excellent water repellent and water sliding properties as a resin for a resist top coat composition. In addition, they found that a base polymer for a resist top coat composition having an excellent pattern profile with fewer development defects could be obtained by combining a repeating unit containing an alkaline-soluble fluorinated alcohol (following general formulae (1a) and (1a)′) with a repeating unit containing a sulfo group (following general formulae (1c) and (1c)′); and as a result, they completed the present invention. Hereinbelow, the resist top coat composition of the present invention will be explained more specifically.

### [Structures of Polymers (P1-1) and (P1-2)]

Polymer (P1-1) to be used in the resist top coat composition of the present invention is characterized in that the polymer contains repeating units represented by the following general formulae (1a), (1b-1), and (1c). Further, polymer (P1-2) to be used in the resist top coat composition of the present invention is characterized in that the polymer contains repeating units represented by the following general formulae (1a)′, (1b-2), and (1c)′.

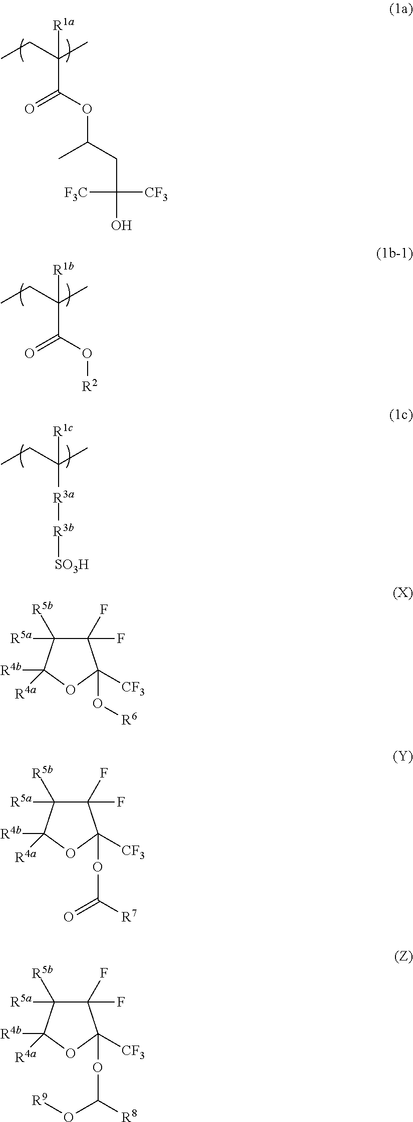

(Wherein, R^{1a} to R^{1c} represent a hydrogen atom or a methyl group. R² represents a group shown by any of the above general formulae (X), (Y), and (Z), and is connected to a —(C═O)—O— bond in repeating unit (1b-1) via any of R^{4a}, R^{4b}, R^{5a}, and R^{5b} in the general formulae (X), (Y), and (Z), wherein R^{4a}, R^{4b}, R^{5a}, and R^{5b} connected to the —(C═O)—O— bond represent a single bond or a linear, a branched, or a cyclic alkylene group having 1 to 15 carbon atoms. Each of R^{4a}, R^{4b}, R^{5a}, and R^{5b} not connected to the —(C═O)—O— bond in repeating unit (1b-1) represents independently any of a hydrogen atom, a hydroxyl group, a halogen atom, and a linear, a branched, and a cyclic monovalent organic group having 1 to 15 carbon atoms, wherein two of R^{4a}, R^{4b}, R^{5a}, and R^{5b} may be bonded with each other to form a cyclic structure. R⁶, R⁷, and R⁹ represent a linear, a branched, or a cyclic alkyl group having 1 to 20 carbon atoms, wherein a part of their hydrogen atoms may be substituted with a halogen atom and a part of a methylene group may be substituted with an oxygen atom or a carbonyl group. R⁸ represents a hydrogen atom, or a linear, a branched, or a cyclic alkyl group having 1 to 20 carbon atoms, wherein a part of their hydrogen atoms may be substituted with a halogen atom and a part of a methylene group may be substituted with an oxygen atom or a carbonyl group. R⁸ and R⁹ may be bonded to form a cyclic structure. R^{3a} represents any of a single bond, —(C═O)—O—, and —(C═O)—NH—. R^{3b} represents a single bond, or a linear, a branched, or a cyclic alkylene group having 1 to 15 carbon atoms. In polymer (P1-1), if total mol of a monomer corresponding to each of the general formulae (1a), (1b-1), and (1c) is made U11, U12, and U13 and total mol of monomers corresponding to entire repeating units contained in polymer (P1-1) is made U1, they are in the following relationships:

0<U11/U1<1,

0<U12/U1<1,

0<U13/U1<1, and

0<(U11+U12+U13)/U1≦1).

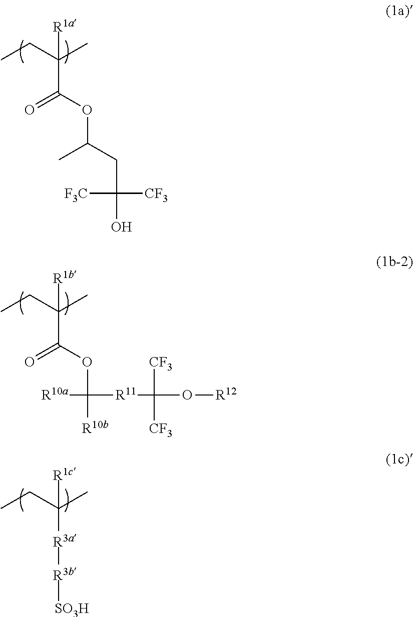

(Wherein, R^{1a′} to R^{1c′} represent a hydrogen atom or a methyl group. R^{10a} and R^{10b} represent a hydrogen atom, or a linear, a branched, or a cyclic monovalent hydrocarbon group having 1 to 15 carbon atoms, wherein R^{10a} and R^{10b} may be bonded with each other to form a non-aromatic ring having 3 to 8 carbon atoms. R¹¹ represents a single bond or a methylene group. R¹² represents any of a linear, a branched, or a cyclic monovalent hydrocarbon group or a fluorinated monovalent hydrocarbon group having 1 to 15 carbon atoms, and an acid labile group, wherein, in the case of a monovalent hydrocarbon group, a constituting —CH₂— group may be substituted with —O— or —C(═O)—. R^{3a′} represents any of a single bond, —(C═O)—O—, and —(C═O)—NH—. R^{3b′} represents a single bond, or a linear, a branched, or a cyclic alkylene group having 1 to 15 carbon atoms. In polymer (P1-2), if total mol of a monomer corresponding to each of the general formulae (1a)′, (1b-2), and (1c)′ is made U11′, U12′, and U13′ and total mol of monomers corresponding to entire repeating units contained in polymer (P1-2) is made U1′, they are in the following relationships:

0<U11′/U1′<1,

0<U12′/U1′<1,

0<U13′/U1′<1, and

0<(U11′+U12′+U13′)/U1′≦1).

R² in the general formula (1b-1) represents a structure represented by the general formulae (X), (Y), and (Z), wherein the general formulae (X), (Y), and (Z) are connected to a —C(═O)— bond of repeating unit (1b-1) via any of R^{4a}, R^{4b}, R^{5a}, and R^{5b}.

An illustrative example of the linear, the branched, or the cyclic monovalent organic group having 1 to 15 carbon atoms of R^{4a}, R^{4b}, R^{5a}, and R^{5b} in the general formulae (X), (Y), and (Z) includes an alkyl group such as a methyl group, an ethyl group, a propyl group, an isopropyl group, a n-butyl group, a sec-butyl group, a tert-butyl group, a tert-amyl group, a n-pentyl group, a n-hexyl group, a n-heptyl group, a n-octyl group, a n-nonyl group, a n-decyl group, a cyclopropyl group, a cyclobutyl group, a cyclopentyl group, a cyclopentyl methyl group, a cyclopentyl ethyl group, a cyclopentyl butyl group, a cyclohexyl group, a cyclohexyl methyl group, a cyclohexyl ethyl group, a cyclohexyl butyl group, a methyl cyclohexyl methyl group, an ethyl cyclohexyl methyl group, an ethyl cyclohexyl ethyl group, a bicyclo[2.2.1]heptyl group, a bicyclo[2.2.1]heptyl methyl group, a bicyclo[2.2.1]heptyl ethyl group, a bicyclo[2.2.1]heptyl butyl group, a methyl bicyclo[2.2.1]heptyl methyl group, an ethyl bicyclo[2.2.1]heptyl methyl group, an ethyl bicyclo[2.2.1]heptyl ethyl group, a bicyclo[2.2.2]octyl group, a bicyclo[2.2.2]octyl methyl group, a bicyclo[2.2.2]octyl ethyl group, a bicyclo[2.2.2]octyl butyl group, a methyl bicyclo[2.2.2]octyl methyl group, an ethyl bicyclo[2.2.2]octyl methyl group, an ethyl bicyclo[2.2.2]octyl ethyl group, a tricyclo[5.2.1.0^{2,6}]decyl group, a tricyclo[5.2.1.0^{2,6}]decyl methyl group, a tricyclo[5.2.1.0^{2,6}]decyl ethyl group, a tricyclo[5.2.1.0^{2,6}]decyl butyl group, a methyl tricyclo[5.2.1.0^{2,6}]decyl methyl group, an ethyl tricyclo[5.2.1.0^{2,6}]decyl methyl group, an ethyl tricyclo[5.2.1.0^{2,6}]decyl ethyl group, an adamantyl group, an adamantyl methyl group, an adamantyl ethyl group, an adamantyl butyl group, a methyl adamantyl methyl group, an ethyl adamantyl methyl group, an ethyl adamantyl ethyl group, a tetracyclo[4.4.0.1^{2,5}.1^{7,10}]dodecyl group, a tetracyclo dodecyl methyl group, a [4.4.0.1^{2,5}.1^{7,10}]tetracyclo[4.4.0.1^{2,5}.1^{7,10}]dodecyl ethyl group, a tetracyclo[4.4.0.1^{2,5}.1^{7,10}]dodecyl butyl group, a tetracyclo[4.4.0.1^{2,5}.1^{7,10}]dodecyl methyl group, an ethyl tetracyclo[4.4.0.1^{2,5}.1^{7,10}]dodecyl methyl group, and an ethyl tetracyclo[4.4.0.1^{2,5}.1^{7,10}]dodecyl ethyl group; an aryl group such as a phenyl group, a methyl phenyl group, a naphthyl group, an anthryl group, and a phenanthryl group; an aralkyl group such as a benzyl group, a diphenyl methyl group, and a phenetyl group; an alkoxy group such as a methoxy group, an ethoxy group, and a propoxy group; and an acyloxy group such as a formyloxy group and an acetoxy group. In addition, a part of hydrogen atoms of these groups may be substituted with a halogen atom, an alkyl group, an aryl group, an alkoxy group, an alkoxycarbonyl group, an oxo group, an alkoxy alkyl group, an acyloxy group, an acyloxy alkyl group, an alkoxy group, and the like. As R^{4a}, R^{4b}, R^{5a}, and R^{5b}, a hydrogen atom, a hydroxyl group, a halogen atom, a methyl group, an ethyl group, a propyl group, a tert-butyl group, and a perfluoroalkyl group are especially preferable.

Further, R^{4a}, R^{4b}, R^{5a}, and R^{5b} which are connected to a —(C═O)—O— bond represent a single bond, or a linear, a branched, or a cyclic alkylene group having 1 to 15 carbon atoms, wherein a group having a form with one hydrogen atom being pulled out from the alkyl group having 1 to 15 carbon atoms in the above examples can be exemplified as the linear, the branched, or the cyclic alkylene group having 1 to 15 carbon atoms.

R^{4a}, R^{4b}, R^{5a}, and R^{5b} may form a ring structure, in an arbitral combination of them, by bonding at least any two of them with each other together with the carbon atoms to which they are bonded. Examples of a typical combination to form the ring are R^{4a} and R^{4b}, R^{4a} and R^{5a}, R^{4a} and R^{5b}, R^{4b} and R^{5a}, R^{4b} and R^{5b}, and R^{5a} and R^{5b}. In this case, an example of the formed ring includes an alicyclic hydrocarbon having 3 to 12 carbon atoms, such as cyclopropane, cyclobutane, cyclopentane, cyclohexane, bicyclo[2.2.1]heptane, bicyclo[2.2.2]octane, tricyclo[5.2.1.0^{2,6}]decane, adamantane, tetracyclo[4.4.0.1^{2,5}.1^{7,10}]dodecane, and a condensed ring having these structures. In addition, a part of hydrogen atoms in these alicyclic hydrocarbons may be substituted with a hydroxyl group, a halogen atom, an alkyl group, an aryl group, an alkoxy group, an alkoxycarbonyl group, an oxo group, an alkoxyalkyl group, an acyloxy group, an acyloxyalkyl group, an alkoxy alkoxy group, or the like.

An illustrative example of the linear, the branched, or the cyclic alkyl group having 1 to 20 carbon atoms of R⁶ in the general formula (X) includes a methyl group, an ethyl group, a propyl group, an isopropyl group, a n-butyl group, a sec-butyl group, a tert-butyl group, a tert-amyl group, a n-pentyl group, a n-hexyl group, a n-heptyl group, a n-octyl group, a n-nonyl group, a n-decyl group, an icosanyl group, a cyclopropyl group, a cyclobutyl group, a cyclopentyl group, a cyclopentyl methyl group, a cyclopentyl ethyl group, a cyclopentyl butyl group, a cyclohexyl group, a cyclohexyl methyl group, a cyclohexyl ethyl group, a cyclohexyl butyl group, a methyl cyclohexyl methyl group, an ethyl cyclohexyl methyl group, an ethyl cyclohexyl ethyl group, a bicyclo[2.2.1]heptyl group, a trifluoromethyl group, a 2,2,2-trifluoroethyl group, a 2,2,3,3,3-pentafluoropropyl group, a 2-methoxyethyl group, a 2-(hexafluoroisopropoxy)ethyl group, a 2-acetoxyethyl group, and an acetonyl group.

An illustrative example of the linear, the branched, or the cyclic alkyl group having 1 to 20 carbon atoms of R⁷ in the general formula (Y) includes a methyl group, an ethyl group, a propyl group, an isopropyl group, a n-butyl group, a sec-butyl group, a tert-butyl group, an isobutyl group, a tert-amyl group, a n-pentyl group, a neopentyl group, a n-hexyl group, a n-heptyl group, a n-octyl group, a n-nonyl group, a n-decyl group, a nonadecyl group, a cyclopropyl group, a cyclobutyl group, a cyclopentyl group, a cyclopentyl methyl group, a cyclopentyl ethyl group, a cyclopentyl butyl group, a cyclohexyl group, a cyclohexyl methyl group, a cyclohexyl ethyl group, a cyclohexyl butyl group, a methyl cyclohexyl methyl group, an ethyl cyclohexyl methyl group, an ethyl cyclohexyl ethyl group, a bicyclo[2.2.1]heptyl group, a trifluoromethyl group, a 2,2,2-trifluoroethyl group, a 2,2,3,3,3-pentafluoropropyl group, a 1-methyl-2,2,2-trifluoroethyl group, a 2-methoxyethyl group, a 2-(hexafluoroisopropoxy)ethyl group, a 2-acetoxyethyl group, and an acetonyl group.

An illustrative example of the linear, the branched, or the cyclic alkyl group having 1 to 20 carbon atoms of R⁸ in the general formula (Z) includes a methyl group, an ethyl group, a propyl group, an isopropyl group, a n-butyl group, a sec-butyl group, a tert-butyl group, an isobutyl group, a tert-amyl group, a n-pentyl group, a 2-pentyl group, a 3-pentyl group, a neopentyl group, a n-hexyl group, a 2-hexyl group, a 3-hexyl group, a n-heptyl group, a n-octyl group, a n-nonyl group, a n-decyl group, an octadecyl group, a cyclopropyl group, a cyclobutyl group, a cyclopentyl group, a cyclopentyl methyl group, a cyclopentyl ethyl group, a cyclopentyl butyl group, a cyclohexyl group, a cyclohexyl methyl group, a cyclohexyl ethyl group, a cyclohexyl butyl group, a methyl cyclohexyl methyl group, an ethyl cyclohexyl methyl group, an ethyl cyclohexyl ethyl group, a bicyclo[2.2.1]heptyl group, a trifluoromethyl group, a 2,2,2-trifluoroethyl group, a 2,2,3,3,3-pentafluoropropyl group, a 1-methyl-2,2,2-trifluoroethyl group, a 2-methoxyethyl group, a 2-(hexafluoroisopropoxy)ethyl group, a 2-acetoxyethyl group, and an acetonyl group.

An illustrative example of the linear, the branched, or the cyclic alkyl group having 1 to 20 carbon atoms of R⁹ in the general formula (Z) includes a methyl group, an ethyl group, a propyl group, an isopropyl group, a n-butyl group, a sec-butyl group, a tert-butyl group, a tert-amyl group, a n-pentyl group, a n-hexyl group, a n-heptyl group, a n-octyl group, a n-nonyl group, a n-decyl group, a cyclopropyl group, a cyclobutyl group, a cyclopentyl group, a cyclopentyl methyl group, a cyclopentyl ethyl group, a cyclopentyl butyl group, a cyclohexyl group, a cyclohexyl methyl group, a cyclohexyl ethyl group, a cyclohexyl butyl group, a methyl cyclohexyl methyl group, an ethyl cyclohexyl methyl group, an ethyl cyclohexyl ethyl group, a bicyclo[2.2.1]heptyl group, a bicyclo[2.2.1]heptyl methyl group, a bicyclo[2.2.1]heptyl ethyl group, a bicyclo[2.2.1]heptyl butyl group, a methyl bicyclo[2.2.1]heptyl methyl group, an ethyl bicyclo[2.2.1]heptyl methyl group, an ethyl bicyclo[2.2.1]heptyl ethyl group, a bicyclo[2.2.2]octyl group, a bicyclo[2.2.2]octyl methyl group, a bicyclo[2.2.2]octyl ethyl group, a bicyclo[2.2.2]octyl butyl group, a methyl bicyclo[2.2.2]octyl methyl group, an ethyl bicyclo[2.2.2]octyl methyl group, an ethyl bicyclo[2.2.2]octyl ethyl group, a tricyclo[5.2.1.0^{2,6}]decyl group, a tricyclo[5.2.1.0^{2,6}]decyl methyl group, a tricyclo[5.2.1.0^{2,6}]decyl ethyl group, a tricyclo[5.2.1.0^{2,6}]decyl butyl group, a methyl tricyclo[5.2.1.0^{2,6}]decyl methyl group, an ethyl tricyclo[5.2.1.0^{2,6}]decyl methyl group, an ethyl tricyclo[5.2.1.0^{2,6}]decyl ethyl group, an adamantyl group, an adamantyl methyl group, an adamantyl ethyl group, an adamantyl butyl group, a methyl adamantyl methyl group, an ethyl adamantyl methyl group, an ethyl adamantyl ethyl group, a tetracyclo[4.4.0.1^{2,5}.1^{7,10}]dodecyl group, a tetracyclo[4.4.0.1^{2,5}.1^{7,10}]dodecyl methyl group, a tetracyclo[4.4.0.1^{2,5}.1^{7,10}]dodecyl ethyl group, a tetracyclo[4.4.0.1^{2,5}.1^{7,10}]dodecyl butyl group, a methyl tetracyclo[4.4.0.1^{2,5}.1^{7,10}]dodecyl methyl group, an ethyl tetracyclo[4.4.0.1^{2,5}.1^{7,10}]dodecyl methyl group, an ethyl tetracyclo[4.4.0.1^{2,5}.1^{7,10}]dodecyl ethyl group, a trifluoromethyl group, a 2,2,2-trifluoroethyl group, a 2,2,3,3,3-pentafluoropropyl group, a 1-methyl-2,2,2-trifluoroethyl group, a 2-methoxyethyl group, a 2-(hexafluoroisopropoxy)ethyl group, a 2-acetoxyethyl group, 2-(1-adamantylcarbonyloxy)ethyl group, and an acetonyl group.

In the general formula (Z), R⁸ and R⁹ may be bonded to form a cyclic structure together with the carbon atom and the oxygen atom to which they are bonded; in that case, an illustrative example of the cyclic structure formed by such bonding includes a tetrahydrofurane ring, a methyl tetrahydrofurane ring, a methoxy tetrahydrofurane ring, a tetrahydropyrane ring, a methyl tetrahydropyrane ring, a methoxy tetrahydropyrane ring, and a 1,4-dioxane ring.

In the general formulae (X), (Y), and (Z), such characteristics as resin's decomposition properties by an acid and an alkali, water repellency, and lipophilicity can be controlled by selecting the best structures as R⁶ to R⁹.

An illustrative example of the linear, the branched, or the cyclic monovalent hydrocarbon group having 1 to 15 carbon atoms of R^{10a}, R^{10b}, and R¹² in the general formula (1b-2) includes a methyl group, an ethyl group, a n-propyl group, an isopropyl group, a n-butyl group, a sec-butyl group, a tert-butyl group, a tert-amyl group, a n-pentyl group, a n-hexyl group, a n-heptyl group, a n-octyl group, a n-nonyl group, a n-decyl group, a cyclopentyl group, a cyclohexyl group, a cyclopentyl methyl group, a cyclopentyl ethyl group, a cyclopentyl butyl group, a cyclohexyl methyl group, a cyclohexyl ethyl group, a cyclohexyl butyl group, and an adamantly group.

Alternatively, in the general formula (1b-2), R^{10a} and R^{10b} may form a non-aromatic ring having 3 to 8 carbon atoms by bonding with each other; but in that case, these groups are an alkylene group having a form with one hydrogen atom being pulled out from the monovalent hydrocarbon group shown above. An illustrative example of the ring includes a cyclopentylene group and a cyclohexylene group.

An illustrative example of the linear, the branched, or the cyclic fluorinated monovalent hydrocarbon group having 1 to 15 carbon atoms of R¹² of the general formula (1b-2) includes a form with a part of or all of hydrogen atoms in the monovalent hydrocarbon group being substituted with a fluorine atom; and an illustrative example of the form includes a trifluoromethyl group, a 2,2,2-trifluoroethyl group, a 3,3,3-trifluoro-1-propyl group, a 3,3,3-trifluoro-2-propyl group, a 2,2,3,3-tetrafluoropropyl group, a 1,1,1,3,3,3-hexafluoroisopropyl group, a 2,2,3,3,4,4,4-heptafluorobutyl group, a 2,2,3,3,4,4,5,5-octafluoropentyl group, a 2,2,3,3,4,4,5,5,6,6,7,7-dodecafluoroheptyl group, a 2-(perfluorobutyl)ethyl group, a 2-(perfluorohexyl)ethyl group, a 2-(perfluorooctyl)ethyl group, and a 2-(perfluorodecyl)ethyl group.

In the general formula (1b-2), an acid labile group can be used as R¹². Various acid labile groups can be used, and an illustrative example of the acid labile group includes groups represented by the following general formulae (L1) to (L4), tertiary alkyl groups of 4 to 20 carbon atoms, preferably 4 to 15 carbon atoms, trialkylsilyl groups in which each alkyl groups of 1 to 6 carbon atoms, and oxoalkyl groups of 4 to 20 carbon atoms.

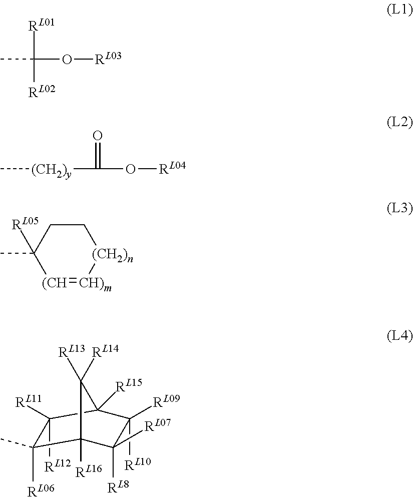

(Wherein, R^{L01} and R^{L02} are hydrogen or linear, branched, or cyclic alkyl groups of 1 to 18 carbon atoms, preferably 1 to 10 carbon atoms. R^{L03} is a monovalent hydrocarbon group of 1 to 18 carbon atoms, preferably 1 to 10 carbon atoms, which may contain a heteroatom such as oxygen, examples of which include unsubstituted linear, branched or cyclic alkyl groups and forms of such alkyl groups in which some hydrogen atoms are replaced by hydroxyl, alkoxy, oxo, amino, alkylamino or the like. R^{L04} is a tertiary alkyl group of 4 to 20 carbon atoms, preferably 4 to 15 carbon atoms, a trialkyl silyl group in which each alkyl group has 1 to 6 carbon atoms, an oxoalkyl group of 4 to 20 carbon atoms, or a group of formula (L1). R^{L05} is an optionally substituted, linear, branched or cyclic alkyl group of 1 to 10 carbon atoms or an optionally substituted aryl group of 6 to 20 carbon atoms. R^{L06} is an optionally substituted, linear, branched or cyclic alkyl group of 1 to 10 carbon atoms or an optionally substituted aryl group of 6 to 20 carbon atoms. R^{L07} to R^{L16} independently represent a hydrogen atom or monovalent substituted or unsubstituted hydrocarbon groups of 1 to 15 carbon atoms. y is an integral of 0 to 6. m is 0 or 1, n is an integral of 0 to 3, and 2 m+n=2 or 3. Broken line denotes a valence bond.

In formula (L1), exemplary R^{L01} and R^{L02} include methyl, ethyl, propyl, isopropyl, n-butyl, sec-butyl, tert-butyl, cyclopentyl, cyclohexyl, 2-ethylhexyl, n-octyl, and adamantyl groups.

R^{L03} is a monovalent hydrocarbon group of 1 to 18 carbon atoms, preferably 1 to 10 carbon atoms, which may contain a heteroatom such as oxygen, examples of which include unsubstituted linear, branched or cyclic alkyl groups and forms of such alkyl groups in which some hydrogen atoms are replaced by hydroxyl, alkoxy, oxo, amino, alkylamino groups or the like. Illustrative examples of the linear, branched or cyclic alkyl groups are as exemplified above for R^{LO1} and R^{LO2}, and examples of the substituted alkyl groups are as shown below.

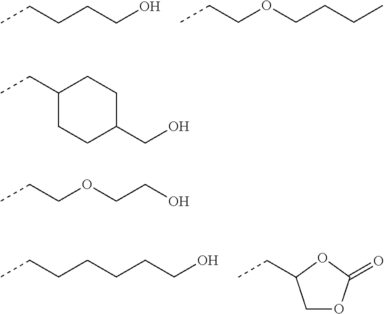

A pair of R^{L01} and R^{L02}, R^{L01} and R^{L03}, or R^{L02} and R^{L03} may together form a ring with carbon or oxygen atoms to which they are bonded. Each of R^{L01}, R^{L02} and R^{L03} is a linear or branched alkylene group of 1 to 18 carbon atoms, preferably 1 to 10 carbon atoms when they form a ring.

In the formula (L2), exemplary tertiary alkyl groups as R^{L04} are tert-butyl, tert-amyl, 1,1-diethylpropyl, 2-cyclopentylpropan-2-yl, 2-cyclohexylpropan-2-yl, 2-(bicyclo[2.2.1]heptan-2-yl)propan-2-yl, 2-(adamantan-1-yl)propan-2-yl, 1-ethylcylopentyl, 1-butylcyclopentyl, 1-ethylcyclohexyl, 1-butylcyclohexyl, 1-ethyl-2-cyclopentenyl, 1-ethyl-2-cyclohexenyl, 2-methyl-2-adamantyl, 2-ethyl-2-adamantyl, and the like. Exemplary trialkylsilyl groups are trimethylsilyl, triethylsilyl, dimethyl-tert-butylsilyl, and the like. Exemplary oxoalkyl groups are 3-oxocyclohexyl, 4-methyl-2-oxooxan-4-yl, 5-methyl-2-oxooxolan-5-yl, and the like.

In the formula (L3), R^{L05} is an optionally substituted, linear, branched or cyclic alkyl group of 1 to 10 carbon atoms or an optionally substituted aryl group of 6 to 20 carbon atoms. Examples of the optionally substituted alkyl groups include linear, branched or cyclic alkyl groups such as methyl, ethyl, propyl, isopropyl, n-butyl, sec-butyl, tert-butyl, tert-amyl, n-pentyl, n-hexyl, cyclopentyl, cyclohexyl, and bicyclo[2.2.1]heptyl, and substituted forms of such groups in which some hydrogen atoms are replaced by hydroxyl, alkoxy, carboxy, alkoxycarbonyl, oxo, amino, alkylamino, cyano, mercapto, alkylthio, sulfo or other groups or in which some methylene groups are replaced by oxygen or sulfur atoms. Examples of optionally substituted aryl groups include phenyl, methylphenyl, naphthyl, anthryl, phenanthryl, and pyrenyl.

In formula (L4), R^{L06} is an optionally substituted, linear, branched or cyclic alkyl group of 1 to 10 carbon atoms or an optionally substituted aryl group of 6 to 20 carbon atoms. Examples of these groups are the same as exemplified for R^{L05}.

R^{L07} to R^{L16} independently represent a hydrogen or monovalent substituted or unsubstituted hydrocarbon groups of 1 to 15 carbon atoms. Exemplary hydrocarbon groups are linear, branched or cyclic alkyl groups such as methyl, ethyl, propyl, isopropyl, n-butyl, sec-butyl, sec-butyl, tert-butyl, tert-amyl, n-pentyl, n-hexyl, n-octyl, n-nonyl, n-decyl, cyclopentyl, cyclohexyl, cyclopentylmethyl, cyclopentylethyl, cyclopentylbutyl, cyclohexylmethyl, cyclohexylethyl, cyclohexylbutyl, and substituted forms of these groups in which some hydrogen atoms are replaced by hydroxyl, alkoxy, carboxy, alkoxycarbonyl, oxo, amino, alkylamino, cyano, mercapto, alkylthio, sulfo or other groups.

Alternatively, R^{L07} to R^{L16} may bond together to form a ring with the carbon atom(s) to which they are bonded (for example, a pair of R^{L07} and R^{L08}, R^{L07} and R^{L09}, R^{L08} and R^{L10}, R^{L09} and R^{L10}, R^{L11} and R^{L12} and R^{L13} and R^{L14} or a similar pair to form a ring). Each of R^{L07} to R^{L16} represents a divalent hydrocarbon group having 1 to 15 carbon atoms when they form a ring, examples of which are those exemplified above for the monovalent hydrocarbon groups, with one hydrogen atom being eliminated. R^{L07} to R^{L16} which are bonded to vicinal carbon atoms may bond together directly to form a double bond (for example, a pair of R^{L07} and R^{L09}, R^{L09} and R^{L15}, R^{L13} and R^{L15}, or a similar pair).

Of the acid labile groups of formula (L1), the linear and branched ones are exemplified by the following groups.

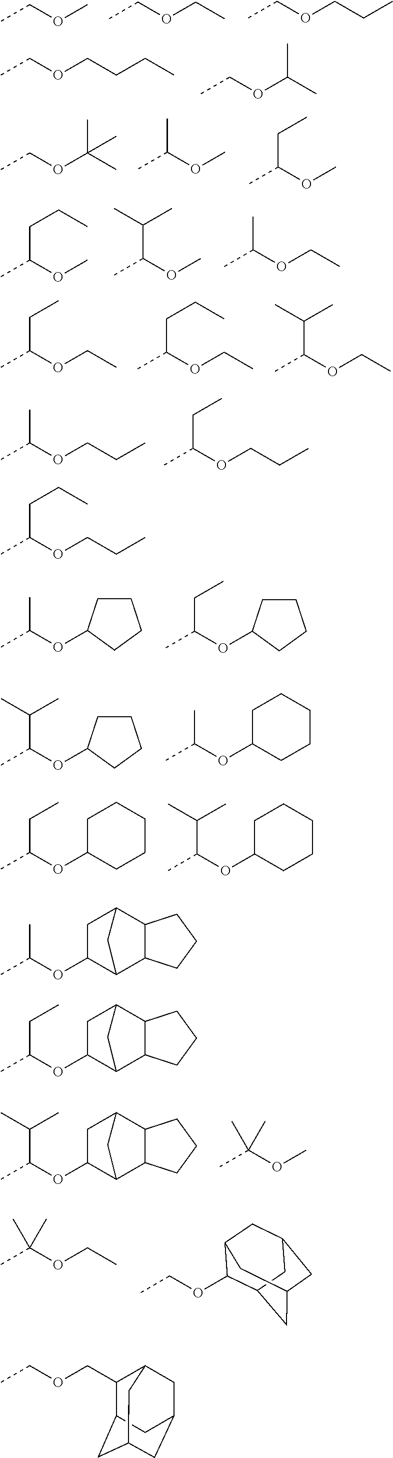

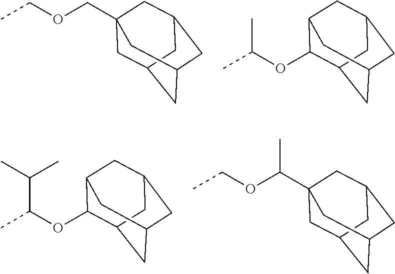

Of the acid labile groups of formula (L1), the cyclic ones are, for example, tetrahydrofuran-2-yl, 2-methyltetrahydrofuran-2-yl, tetrahydropyran-2-yl, 2-methyltetrahydropyran-2-yl, and the like.

Examples of the acid labile groups of formula (L2) include tert-butoxycarbonyl, tert-butoxycarbonylmethyl, tert-amyloxycarbony, tert-amyloxycarbonylmethyl, 1,1-diethylpropyloxycarbony, 1,1-diethylpropyloxycarbonylmethyl, 1-ethylcyclopentyloxycarbonyl, 1-ethylcyclopentyloxycarbonylmethyl, 1-ethyl-2-cyclopentenyloxycarbonyl, 1-ethyl-2-cyclopentenyloxycarbonylmethyl, 1-ethoxy-ethoxycarbonylmethyl, 2-tetrahydropyranyloxycarbonylmethyl, and 2-tetrahydrofuranyloxycarbonylmethyl groups.

Examples of the acid labile groups of formula (L3) include 1-methylcyclopentyl, 1-ethylcyclopentyl, 1-n-propylcyclopentyl, 1-isopropylcyclopentyl, 1-n-butylcyclopentyl, 1-sec-butylcyclopentyl, 1-cyclohexylcyclopentyl, 1-(4-methoxybutyl)cyclopentyl, (bicyclo[2.2.1]heptan-2-yl)cyclopentyl, 1-(7-oxabicyclo[2.2.1]heptan-2-yl)cyclopentyl, 1-methylcyclohexyl, 1-ethylcyclohexyl, 3-methyl-1-cyclopenten-3-yl, 3-ethyl-1-cyclopenten-3-yl, 3-methyl-1-cyclohexen-3-yl, 3-ethyl-1-cyclohexen-3-yl groups.

Of the acid labile groups of formula (L4), those groups of the following formulae (L4-1) to (L4-4) are particularly preferred.

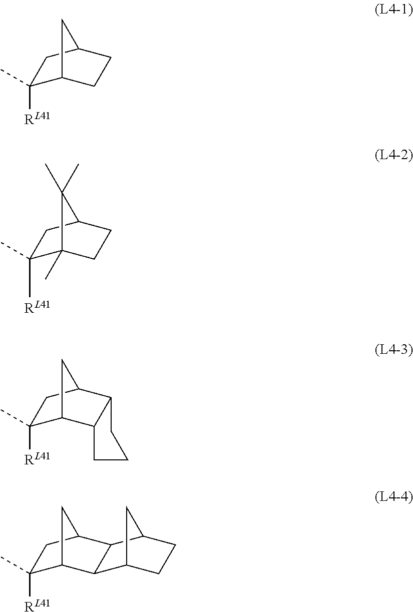

(R^{L41} is each independently a monovalent hydrocarbon group, typically a linear, branched or cyclic alkyl group having 1 to 10 carbon atoms. The broken line denotes a bonding site and direction.)

Examples of the monovalent hydrocarbon group of R^{L41} in the general formula (L4-1) to (L4-4) include methyl, ethyl, propyl, isopropyl, n-butyl, sec-butyl, tert-butyl, tert-amyl, n-pentyl, n-hexyl, cyclopentyl, cyclohexyl groups.

For the general formulae (L4-1) to (L4-4), there can exist enantiomers and diastereomers. Each of formulae (L4-1) to (L4-4) collectively represents all such stereoisomers. Such stereoisomers may be used alone or in admixture.

For example, the general formula (L4-3) represents one or mixture of two selected from groups of the following general formulae (L4-3-1) and (L4-3-2).

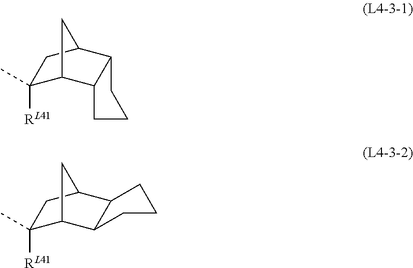

(In the formula, R^{L41} represents the same as those in the above-mentioned.)

Similarly, the general formula (L4-4) represents one or mixture of two or more selected from groups of the following general formulae (L4-4-1) to (L4-4-4).

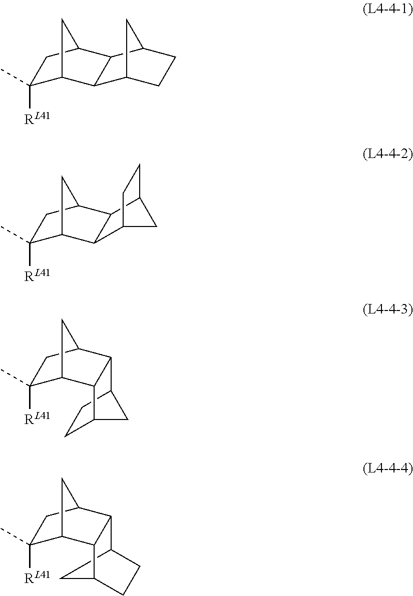

(In the formula, R^{L41} represents the same as those in the above-mentioned.)

Each of formulae (L4-1) to (L4-4), (L4-3-1) and (L4-3-2), and (L4-4-1) to (L4-4-4) collectively represents an enantiomer thereof and a mixture of enantionmers.

It is noted that in the above formulae (L4-1) to (L4-4), (L4-3-1) and (L4-3-2), and (L4-4-1) to (L4-4-4), the bond direction is on the exo side relative to the bicyclo[2.2.1]heptanes's ring, which ensures high reactivity for acid catalyzed elimination reaction (see Japanese Patent Laid-open (Kokai) No. 2000-336121). In preparing these monomers having a tertiary exo-alkyl group of bicyclo[2.2.1]heptanes structure as a substituent group, there may be contained monomers substituted with a an endo-alkyl group as represented by the following formulae (L4-1-endo) to (L4-4-endo). For good reactivity, an exo proportion of at least 50 mol % is preferred, with an exo proportion of at least 80 mol % being more preferred.

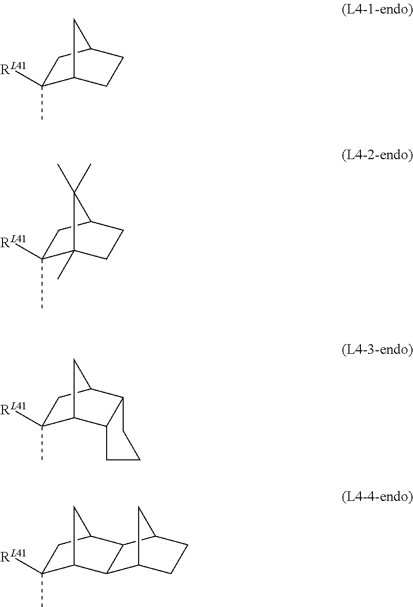

(In the formula, R^{L41} represents the same as those in the above-mentioned.)

Illustrative examples of the acid labile group of formula (L4) are given below.

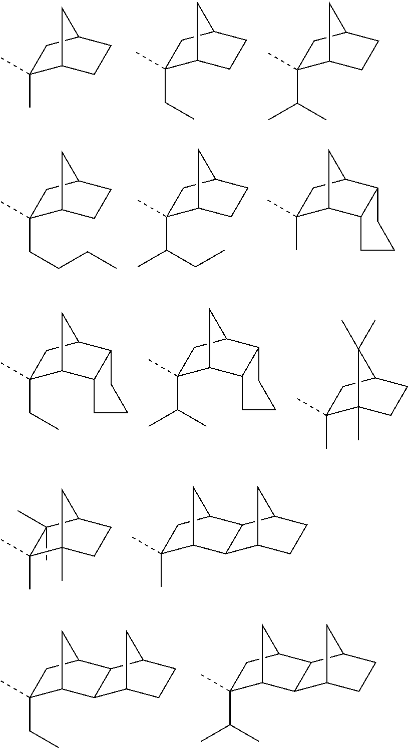

Examples of the tertiary alkyl groups having 4 to 20 carbon atoms as an acid labile group of R¹² include tert-butyl, tert-amyl, 1,1-diethylpropyl, 2-cyclopentylpropan-2-yl, 2-cyclohexylpropan-2-yl, 2-(bicyclo[2.2.1]heptan-2-yl)propan-2-yl, 2-(adamantan-1-yl)propan-2-yl, 1-ethylcylopentyl, 1-butylcyclopentyl, 1-ethylcyclohexyl, 1-butylcyclohexyl, 1-ethyl-2-cyclopentenyl, 1-ethyl-2-cyclohexenyl, 2-methyl-2-adamantyl, 2-ethyl-2-adamantyl, and the like. Exemplary trialkylsilyl groups are trimethylsilyl, triethylsilyl, and dimethyl-tert-butylsilyl. Exemplary oxoalkyl groups are 3-oxocyclohexyl, 4-methyl-2-oxooxan-4-yl, and 5-methyl-2-oxooxolan-5-yl.

In the general formula (1c) and (1C)′, an illustrative example of a linear, a branched, or a cyclic alkylene group having 1 to 15 carbon atoms of R^{3b} and R^{3b′} includes a group having a form with one hydrogen atom being pulled out from the alkyl group exemplified in the above examples as R^{4a}, R^{4b}, R^{5a} and R^{5b}.

Examples of the repeating unit of the general formula (1b-1) are given below, but not limited thereto.

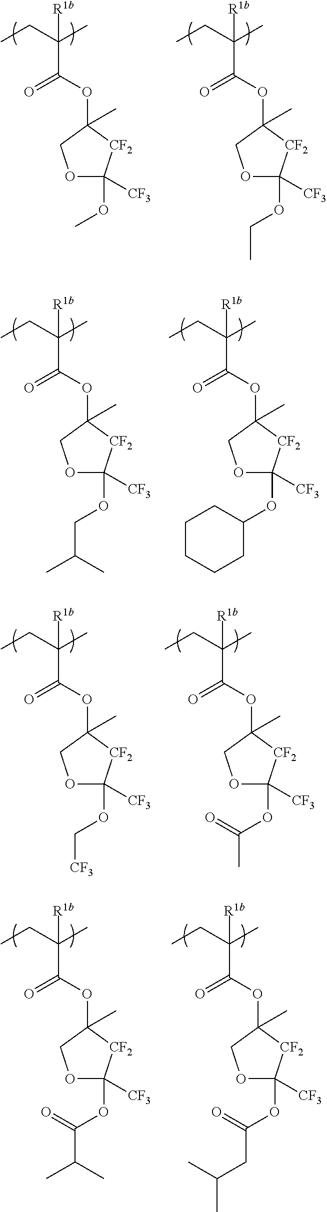

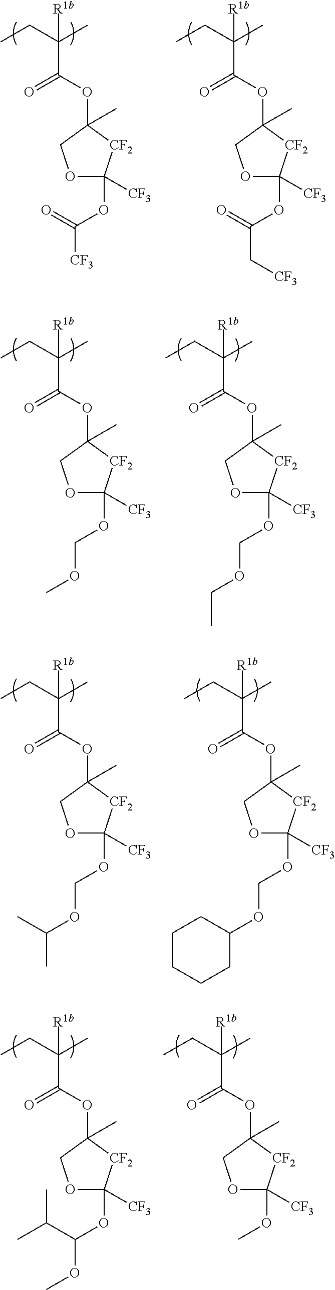

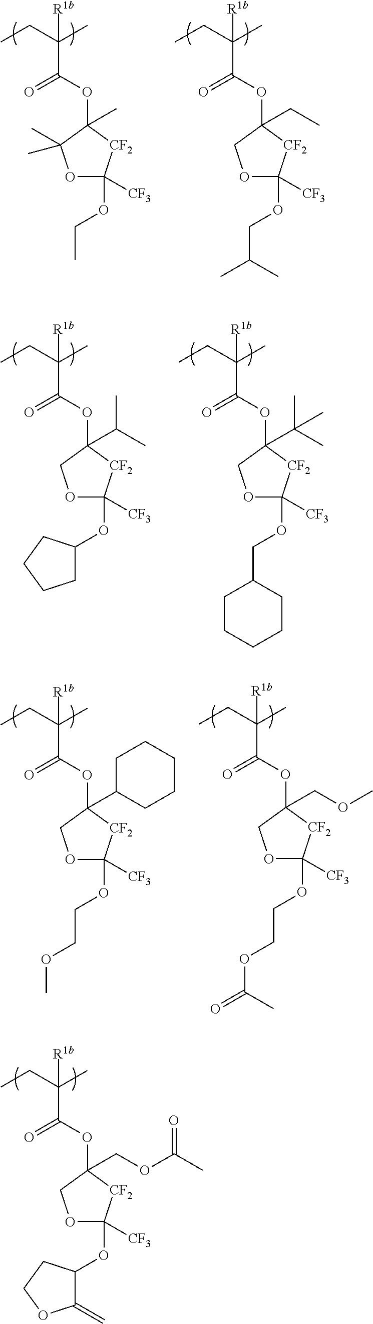

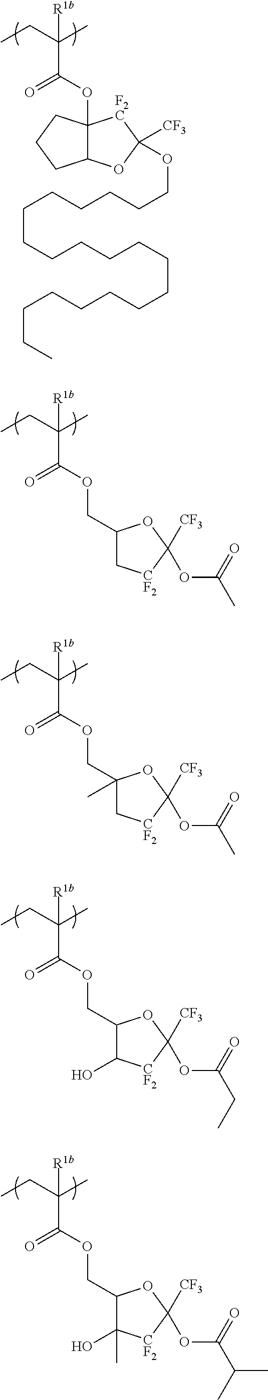

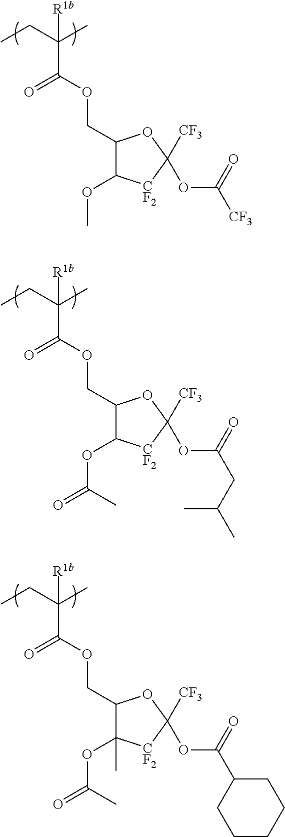

(In the formula, R^{1b} represents the same as those in the above-mentioned.)

Examples of the repeating unit of the general formula (1b-2) are given below, but not limited thereto.

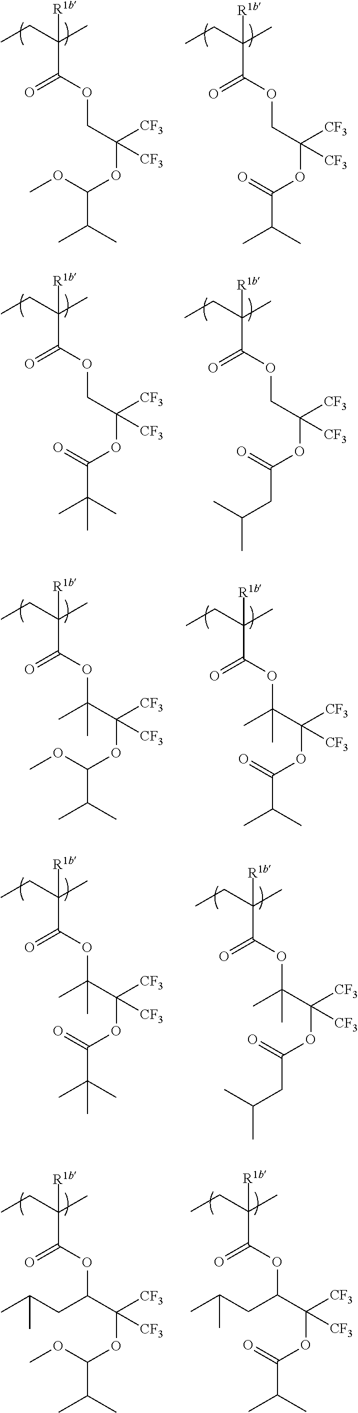

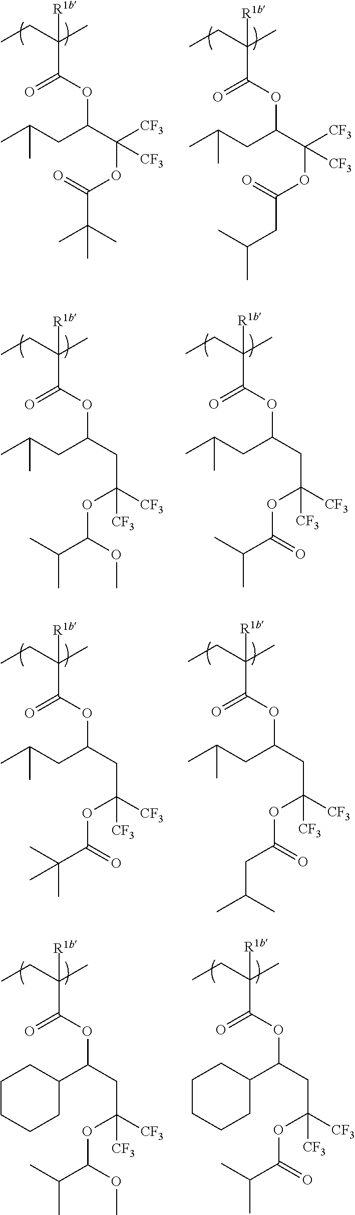

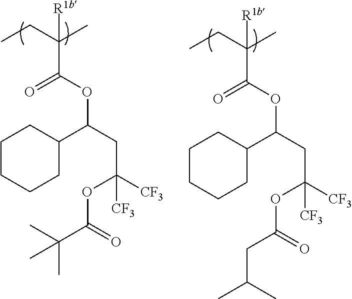

(In the formula, R^{1b′} represent the same as those in the above-mentioned.)

Examples of the repeating unit of the general formula (1c) are given below, but not limited thereto. Examples of the general formula (1c)′ are repeating units having a following structure in which R^{1c} is changed by R^{1c}.

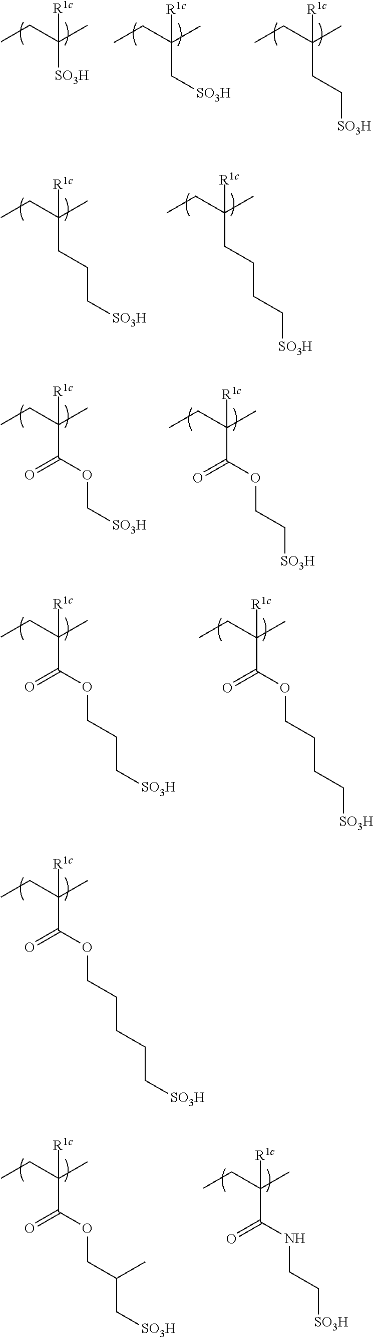

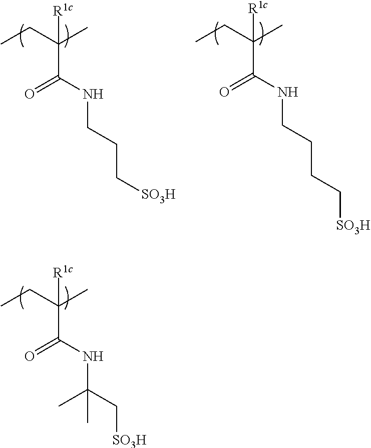

(In the formula, R^{1c} and R^{1c′} represent the same as those in the above-mentioned.)

In polymers (P1-1) and (P1-2), repeating units represented by the general formulae (1a) and (1a) not only contribute solubility into an alkaline developer but also express performance of excellent water repellent and water sliding properties. Structure of a side chain in the repeating units represented by the general formulae (1b-1) and (1b-2), such as number of carbon atoms, degree of branching, and number of fluorine atoms, can be easily controlled, so that a polymer showing necessary performance as a resist top coat composition with regard to water repellent and water sliding properties, lipophilicity, and decomposition properties by an acid and a hydrolysis can be manufactured. In addition to these repeating units, by combining them with a repeating unit having a sulfo group (general formulae (1c) and (1c)′), a base polymer for a resist top coat composition having an excellent pattern profile with fewer development defects can be obtained.

Polymer (P1-1) can be afforded with an ability to be hydrolyzed by an alkali as appropriate; and in this case, it is preferable to contain a repeating unit represented by the general formula (Y). A hemiacetal hydroxyl group has a higher acidity as compared with an alcoholic hydroxyl group; but an ester bond in the general formula (Y) is the ester between a carboxylic acid and a hemiacetal hydroxyl group having a further higher acidity because of five fluorine atoms bonded to the neighboring carbon atoms, that is, a sort of a mixed acid anhydride. Accordingly, the ester bond is susceptible to an alkaline hydrolysis far more easily as compared with an ester between an ordinary alcohol and a carboxylic acid; and thus it is assumed that hydrolysis by, for example, an alkaline developer and the like may take place easily.

It is also possible to afford polymer (P1-1) with an ability to be hydrolyzed by an acid as appropriate; and in this case, it is preferable to contain a repeating unit represented by the general formula (Z). In the general formula (Z), an acid labile acetal structure (—O—CH(R⁸)—OR⁹) is present, which is assumed to be easily hydrolyzed, for example, if an acid derived from an acid generator is present nearby.

It is also possible to afford polymer (P1-2) with an ability to be hydrolyzed by an alkali as appropriate. A fluorine-containing alcoholic hydroxyl group has a higher acidity as compared with an ordinary alcohol; and thus, R¹², having a structure of —C(═O)—R in a repeating unit represented by the general formula (1b-2), forms an ester between a carboxylic acid and an alcoholic hydroxyl group having an enhanced acidity, that is a sort of a mixed acid anhydride. Accordingly, the ester is susceptible to alkaline hydrolysis far more easily as compared with an ester between an ordinary alcohol and a carboxylic acid; and thus it is assumed that hydrolysis by, for example, an alkaline developer and the like may take place easily.

Further, it is also possible to afford polymer (P1-2) with an ability to be hydrolyzed by an acid as appropriate. For example, in the case that R¹² in a repeating unit represented by the general formula (1b-2) has an acid labile acetal structure, it is assume that decomposition by an acid derived from an acid generator takes place easily.

In the case that, in polymer (P1-1), an ester bond in the general formula (Y) is hydrolyzed, or an acetal structure in the general formula (Z) is decomposed, a highly hydrophilic hemiacetal structure is formed, resulting in decrease of a contact angle on surface of the polymer, especially a contact angle after development, so that it may contribute to decrease of a blob defect. Further, when a side chain of repeating unit (1b-2) in polymer (P1-2) is decomposed by an acid or an alkali to form a fluorine-containing alcohol structure, an affinity to an alkaline developer is increased so that the defect may be decreased.

In addition to repeating units represented by the general formulae (1a), (1b-1), and (1c) (in the case of polymer (P1-1)) and repeating units represented by the general (1a)′, (1b-2), and (1c)′ (in the case of polymer (P1-2)), when one or two or more of repeating units represented by the following general formulae (2a) to (2i) co-exist, a resist top coat composition, having further excellent water repellent and water sliding properties, alkaline-solubility, and contact angle after development, can be realized.

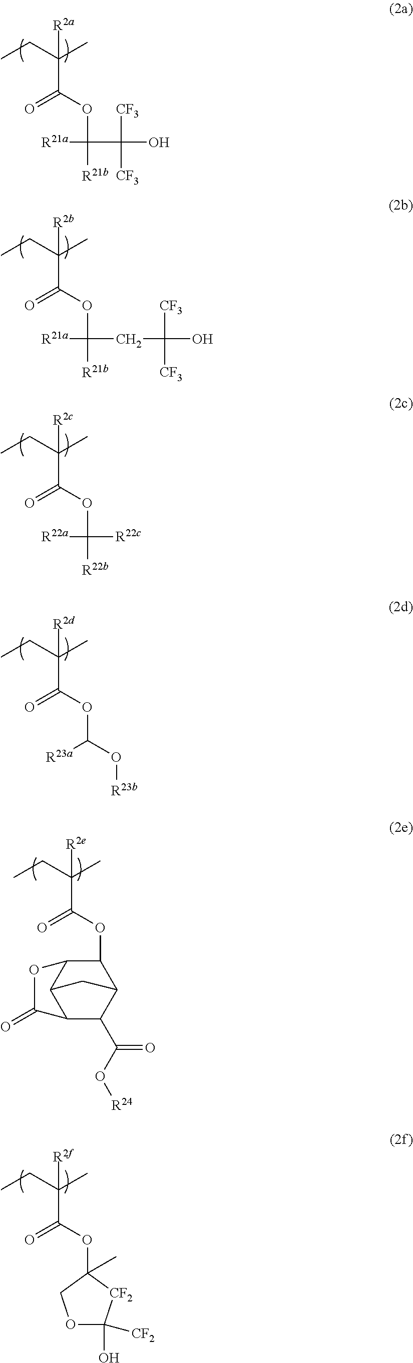

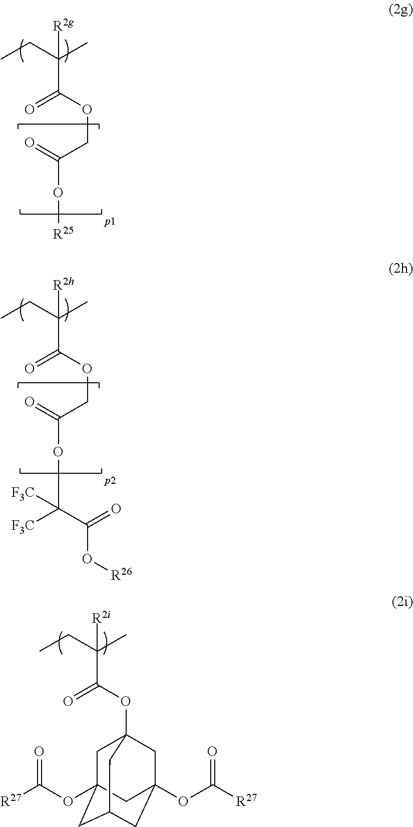

(Wherein, R^{2a} to R²ⁱ represent a hydrogen atom or a methyl group. R^{21a} and R^{21b} represent a hydrogen atom, or a linear, a branched, or a cyclic monovalent hydrocarbon group having 1 to 15 carbon atoms, wherein R^{21a} and R^{21b} may be bonded with each other, together with the carbon atoms to which they are bonded, to form a non-aromatic ring having 3 to 8 carbon atoms. Here, a combination of (R^{21a}, R^{21b})=(hydrogen atom, methyl group) in the general formula (2b) is excluded. R^{22a}, R^{22b}), and R^{22c} represent a hydrogen atom, or a linear, a branched, or a cyclic monovalent hydrocarbon group or a fluorine-containing hydrocarbon group having 1 to 15 carbon atoms, wherein R^{22a} and R^{22b}, R^{22a} and R^{22c}, and R^{22b} and R^{22c} may be bonded with each other, together with the carbon atoms to which they are bonded, to form a non-aromatic ring having 3 to 8 carbon atoms. R^{23a} represents a hydrogen atom, or a linear, a branched, or a cyclic monovalent hydrocarbon group having 1 to 15 carbon atoms. R^{23b} represents a linear, a branched, or a cyclic monovalent hydrocarbon group having 1 to 15 carbon atoms, wherein R^{23a} and R^{23b} may be bonded with each other, together with the carbon atom and the oxygen atom to which they are bonded, to form a non-aromatic ring having 3 to 8 carbon atoms. R²⁴ and R²⁷ represent a linear, a branched, or a cyclic fluorinated monovalent hydrocarbon group having 1 to 15 carbon atoms. R²⁵ and R²⁶ represent a linear, a branched, or a cyclic monovalent hydrocarbon group or a fluorinated monovalent hydrocarbon group having 1 to 15 carbon atoms. Reference characters p1 and p2 represent an integer of 0 to 6).

An illustrative example of the linear, the branched, or the cyclic monovalent hydrocarbon group having 1 to 15 carbon atoms in R^{21a}, R^{21b}, R^{22a} to R^{22c}, R^{23a}, R^{23b}, R²⁵, and R²⁶ includes a methyl group, an ethyl group, a n-propyl group, an isopropyl group, a n-butyl group, a sec-butyl group, a tert-butyl group, a tert-amyl group, a n-pentyl group, a n-hexyl group, a n-heptyl group, a n-octyl group, a n-nonyl group, a n-decyl group, a cyclopentyl group, a cyclohexyl group, a cyclopentyl methyl group, a cyclopentyl ethyl group, a cyclopentyl butyl group, a cyclohexyl methyl group, a cyclohexyl ethyl group, a cyclohexyl butyl group, and an adamantly group. R^{21a} and R^{21b}, R^{22a} and R^{22b}, R^{22a} and R^{22c}, R^{22b} and R^{22c}, and R^{23a} and R^{23b} may be bonded with each other to form a non-aromatic ring having 3 to 8 carbon atoms, wherein these groups are an alkylene group having a form with one hydrogen atom being pulled out from the exemplified monovalent hydrocarbon group; and an illustrative example of the ring includes a cyclopentylene group and a cyclohexylene group.

An illustrative example of the linear, the branched, or the cyclic fluorinated monovalent hydrocarbon group having 1 to 15 carbon atoms in R^{22a} to R^{22c} and R²⁴ to R²⁷ is a form with a part or all of hydrogen atoms of the monovalent hydrocarbon group being substituted with a fluorine atom; and illustrative example of the form includes a trifluoromethyl group, a 2,2,2-trifluoroethyl group, a 3,3,3-trifluoro-1-propyl group, a 3,3,3-trifluoro-2-propyl group, a 2,2,3,3-tetrafluoropropyl group, a 1,1,1,3,3,3-hexafluoroisopropyl group, a 2,2,3,3,4,4,4-heptafluorobutyl group, a 2,2,3,3,4,4,5,5-octafluoropentyl group, a 2,2,3,3,4,4,5,5,6,6,7,7-dodecafluoroheptyl group, a 2-(perfluorobutyl)ethyl group, a 2-(perfluorohexyl)ethyl group, a 2-(perfluorooctyl)ethyl group, and a 2-(perfluorodecyl)ethyl group.

An illustrative example of the repeating unit represented by the general formulae (2a) to (2i) includes the followings, but is not limited to them.

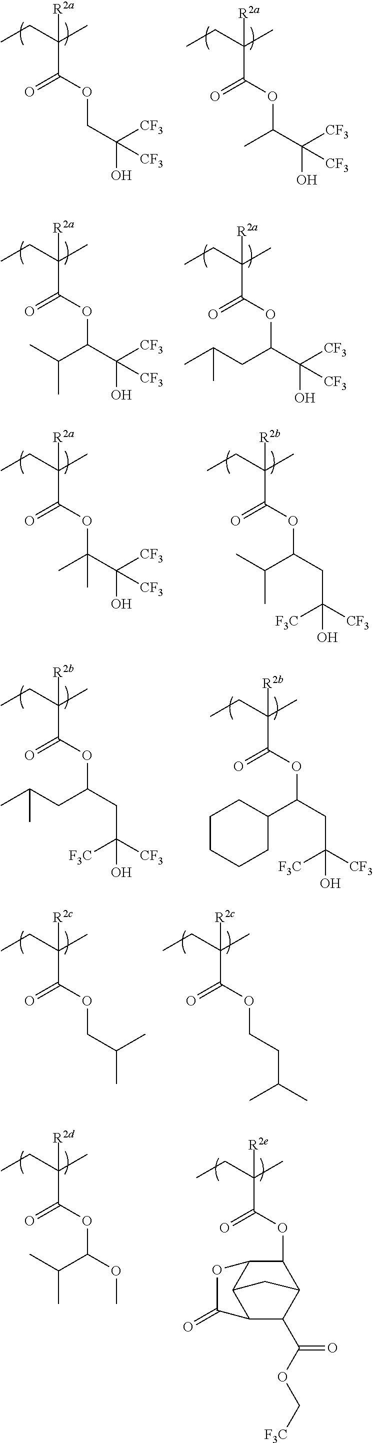

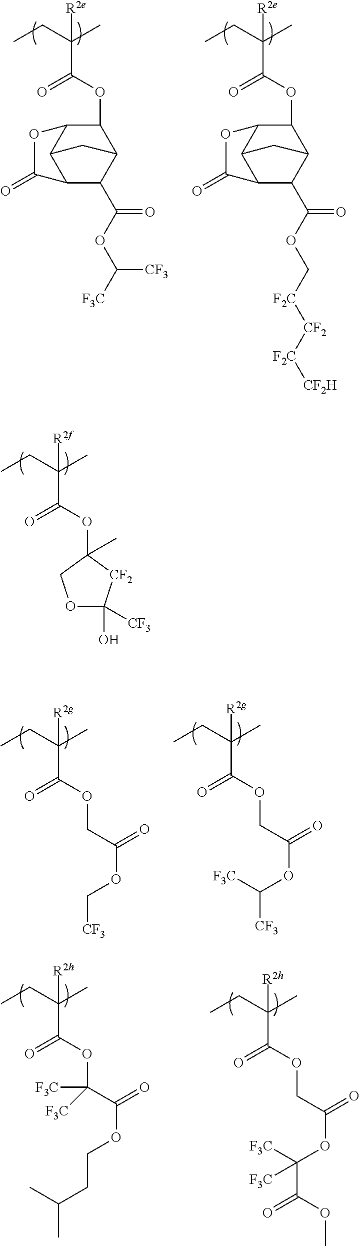

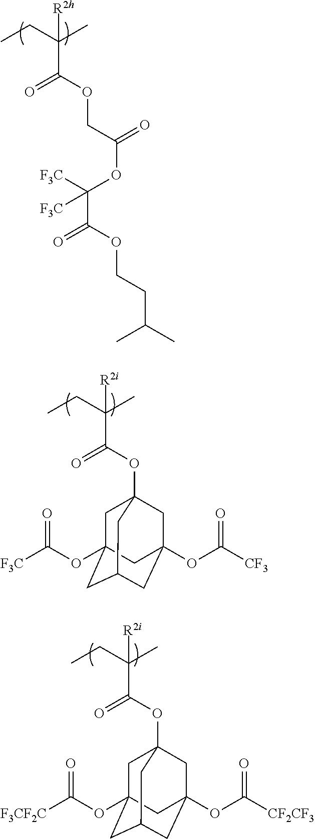

(Wherein, R^{2a} to R²ⁱ represent the same as those in the above-mentioned.)

Polymers (P1-1) and (P1-2) of the present invention can express sufficient performance only by a combination of repeating units represented by (2a) to (2i), in addition to the general formulae of (1a), (1b-1), and (1c) (in the case of polymer (P1-1)) and the general formulae of (1a)′, (1b-2), and (1c)′ (in the case of polymer (P1-2)); but to afford the polymers with further water repellent and water sliding properties and to control an alkaline-solubility and an affinity to a developer, the polymers may be composed further with any one or a combination of any two or more of repeating units represented by the following general formulae (3a) to (3e), (4a) to (4e), and (5a) to (5c).

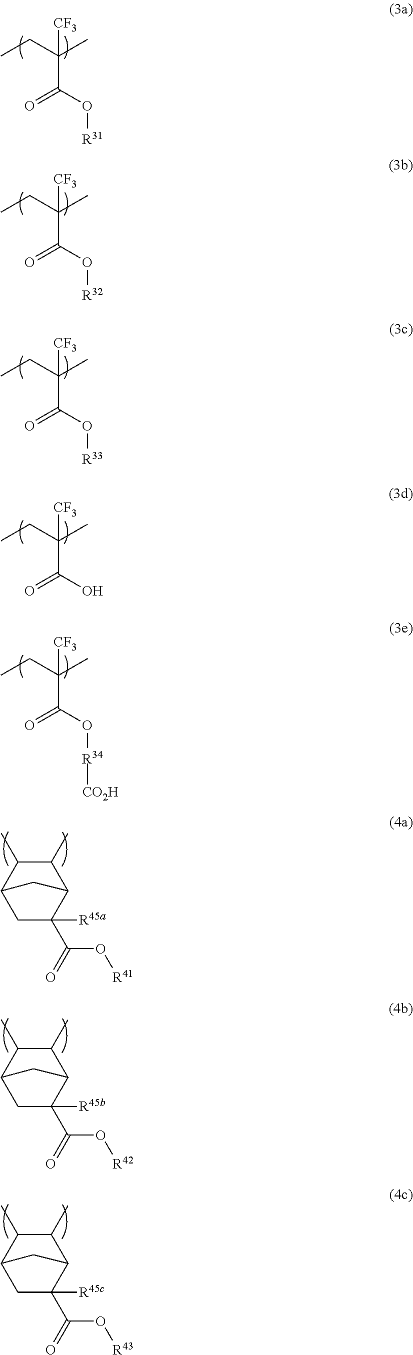

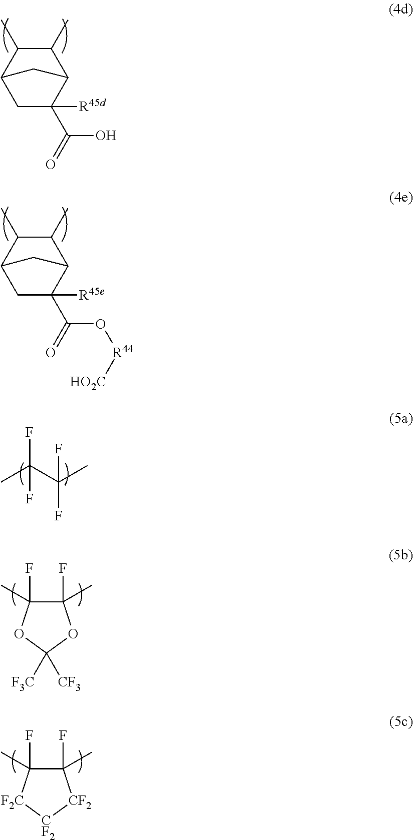

(Wherein, R³¹ and R⁴¹ represent a monovalent hydrocarbon group or a fluorinated monovalent hydrocarbon group having 1 to 15 carbon atoms. R³² and R⁴² represent an adhesion group. R³³ and R⁴³ represent an acid labile group. R³⁴ and R⁴⁴ represent a single bond or an organic divalent group having 1 to 15 carbon atoms. R^{45a} to R^{45e} represent a hydrogen atom, a methyl group, or a trifluoromethyl group.)

An illustrative example of the monovalent hydrocarbon group having 1 to 15 carbon atoms of R³¹ and R⁴¹ includes a methyl group, an ethyl group, a n-propyl group, an isopropyl group, a n-butyl group, a sec-butyl group, a tert-butyl group, a tert-amyl group, a n-pentyl group, a n-hexyl group, a n-heptyl group, a n-octyl group, a n-nonyl group, a n-decyl group, a cyclopentyl group, a cyclohexyl group, a cyclopentyl methyl group, a cyclopentyl ethyl group, a cyclopentyl butyl group, a cyclohexyl methyl group, a cyclohexyl ethyl group, a cyclohexyl butyl group, and an adamantly group; and a illustrative example of the linear, the branched, or the cyclic fluorinated monovalent hydrocarbon group having 1 to 15 carbon atoms includes a trifluoromethyl group, a 2,2,2-trifluoroethyl group, a 3,3,3-trifluoro-1-propyl group, a 3,3,3-trifluoro-2-propyl group, a 2,2,3,3-tetrafluoropropyl group, a 1,1,1,3,3,3-hexafluoroisopropyl group, a 2,2,3,3,4,4,4-heptafluorobutyl group, a 2,2,3,3,4,4,5,5-octafluoropentyl group, a 2,2,3,3,4,4,5,5,6,6,7,7-dodecafluoroheptyl group, a 2-(perfluorobutyl)ethyl group, a 2-(perfluorohexyl)ethyl group, a 2-(perfluorooctyl)ethyl group, and a 2-(perfluorodecyl)ethyl group.

An adhesion group of R³² and R⁴² are selected from various examples; the groups shown below are particularly preferred.

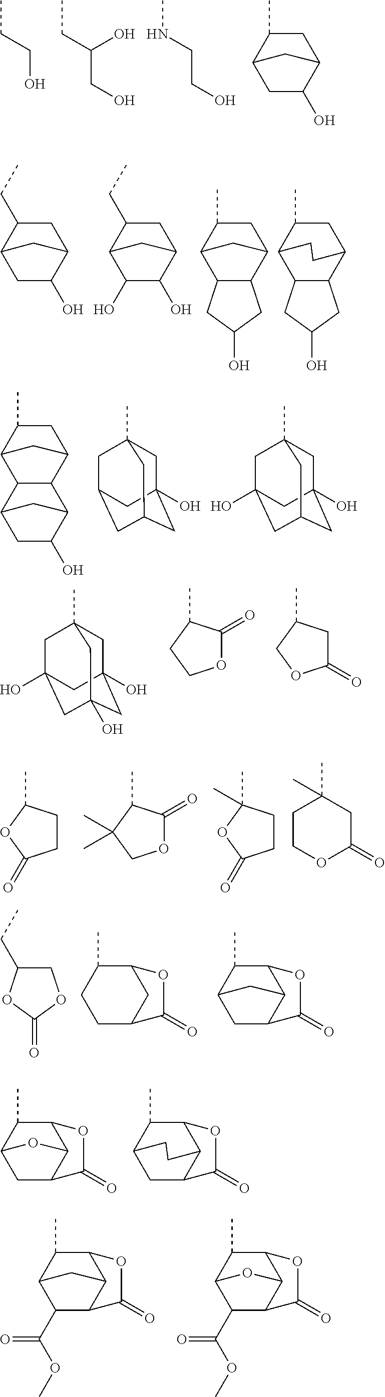

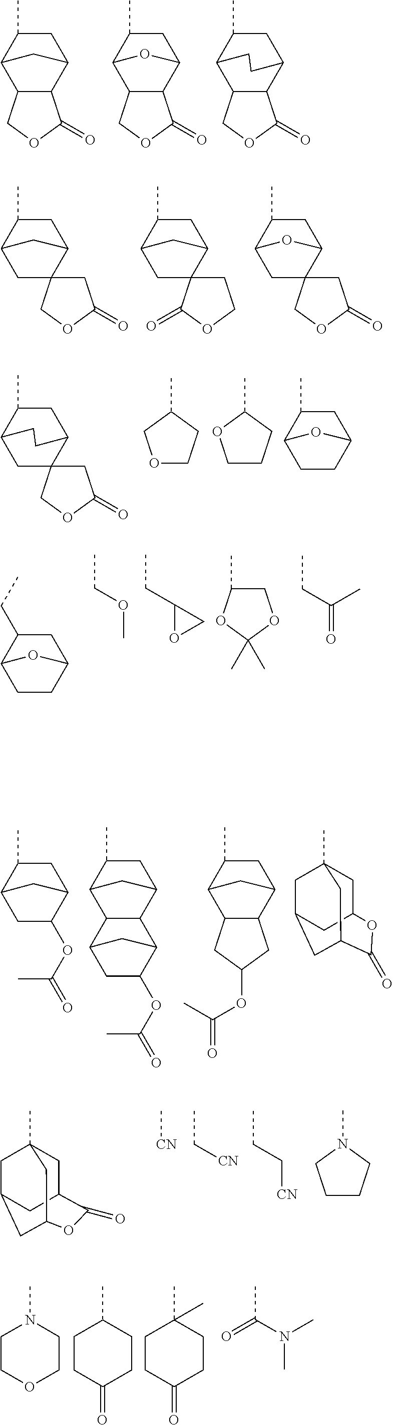

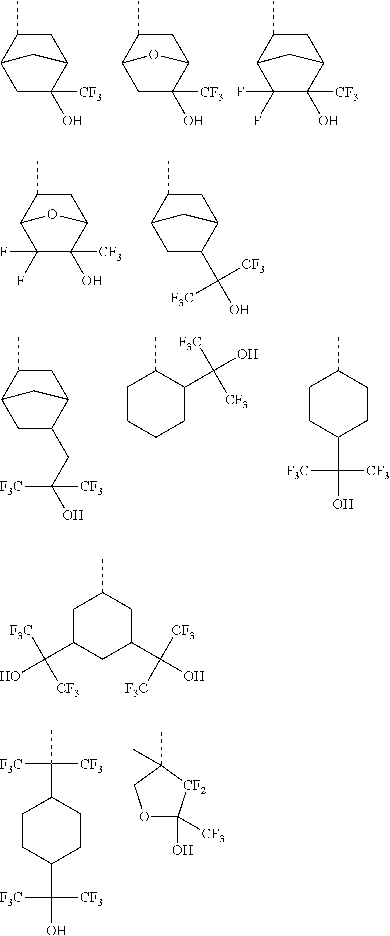

(In the formulae, broken line denotes a valence bond.)

Examples of the acid labile groups of R³³ and R⁴³ include the same as the groups described above.

Examples of the divalent organic group having 1 to 15 carbon atoms of R³³ and R⁴³ include the above-described monovalent groups from which a hydrogen atom is pulled up (for example, methylente and ethylene groups). In addition, the following groups can be used.

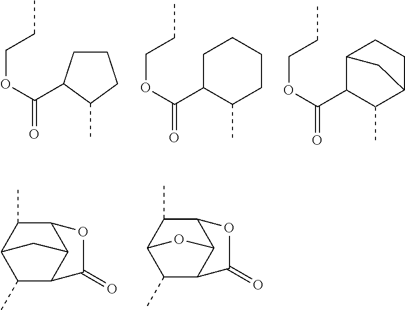

(In the formula, broken line denotes a valence bond.)

Alternatively, in polymer (P1-1) of the present invention, a repeating unit represented by the general formula (1c) may be present as the form of repeating unit (1c^{s}) wherein a part of its sulfo group is neutralized by a basic compound, as shown by the below formula. Similarly, in polymer (P1-2), a repeating unit represented by the general formula (1c)′ may be present as the form of repeating unit (1c^{s})′ wherein a part of its sulfo group is neutralized by a basic compound.

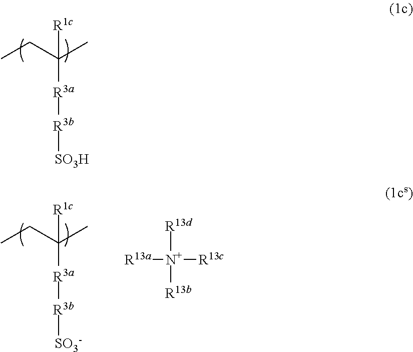

(Wherein, R^{1c}, R^{3a}, and R^{3b} represent the same as those in the above-mentioned. Each R^{13a} to R^{13d} independently represents a hydrogen atom; or a linear, a branched, or a cyclic alkyl group, or an alkenyl group, or an oxoalkyl group, or an oxoalkenyl group having 1 to 12 carbon atoms; or an aryl group having 6 to 20 carbon atoms; or an aralkyl group or an aryl oxoalkyl group having 7 to 12 carbon atoms. R^{13a} to R^{13d} may be substituted with an alkoxy group in its part of or all of hydrogen atoms, and may contain a nitrogen atom, an ether group, an ester group, a hydroxyl group, and a carboxy group. R^{13a} and R^{13b}, and R^{13a} and R^{13b} and R^{13c} may be bonded with each other to form a ring having 5 to 10 carbon atoms; in this case, R^{13a} and R^{13b}, and R^{13a} and R^{13b} and R^{13c} each represents an alkylene group, and may contain a nitrogen atom in the ring.)

In the general formula (1c^{s}), an ammonium salt (a cationic part) formed by R^{13a} to R^{13d} can be obtained by a neutralization reaction of a corresponding amine compound. In this case, an amine compound such as a primary, a secondary, and a tertiary aliphatic amine, a mixed amine, an aromatic amine, a heterocyclic amine, a nitrogen-containing compound having a carboxy group, a nitrogen-containing compound having a sulfonyl group, a nitrogen-containing compound having a hydroxyl group, a nitrogen-containing compound having a hydroxyphenyl group, an amide, an imide, and a carbamate can be used; and an illustrative example of them includes the compounds described in paragraphs [0146] to [0164] in Japanese Patent Laid-open (Kokai) No. 2008-111103.

An illustrative example of the repeating unit shown by the general formula (1c^{s}) includes the followings, but is not limited to them.

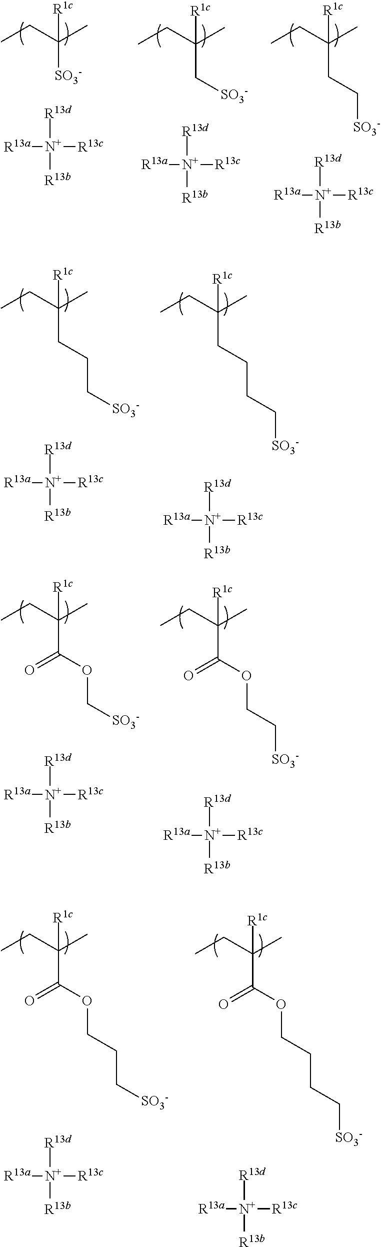

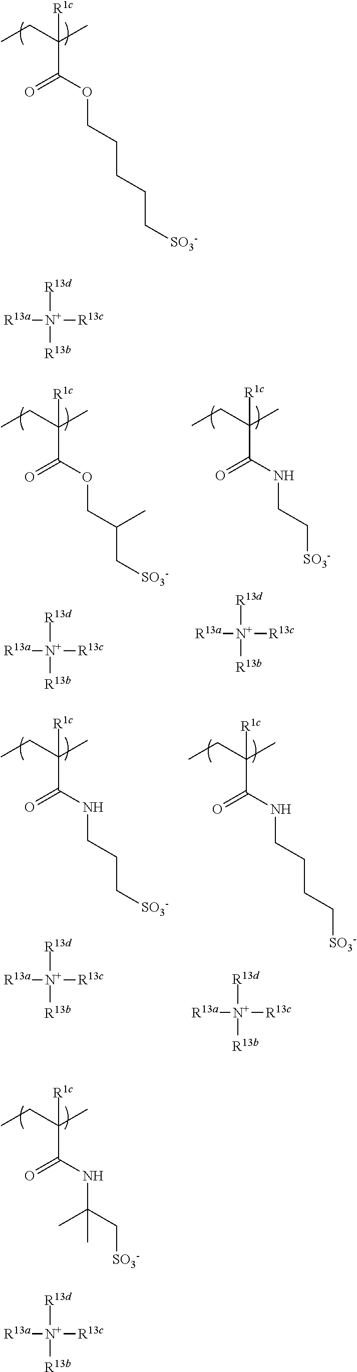

(Wherein, R^{1c} and R^{13a} to R^{13d} represent the same as those in the above-mentioned.)

In the resist top coat composition of the present invention, even polymer (P1-1) or polymer (P1-2) alone can adequately express the performance. However, in order to increase water repellent and water sliding properties further and to control an alkaline-solubility and an affinity to a developer, polymer (P2) having repeating units represented by the following general formulae (i) to (iv), in addition to polymer (P1-1) or polymer (P1-2), can be blended for use.

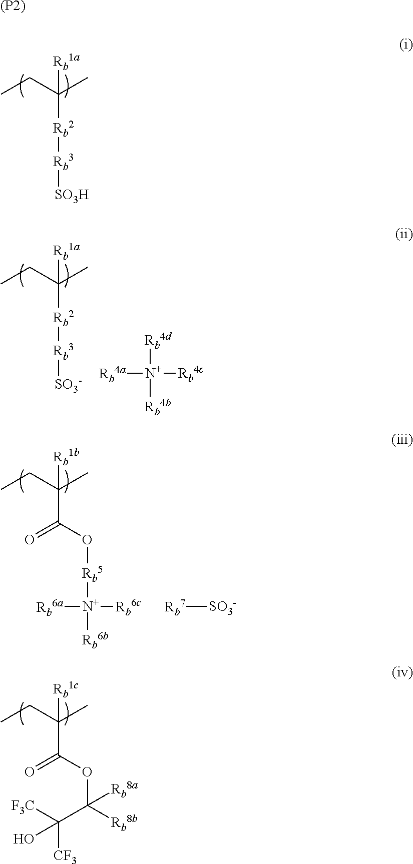

(Wherein, R_{b}^{1a} to R_{b}^{1c} represent a hydrogen atom or a methyl group. R_{b}² represents any of a single bond, an alkylene group having 1 to 4 carbon atoms, a phenylene group, —C(═O)—O—, and —C(═O)—NH—. R_{b}³ represents any of a single bond, and a linear, a branched, or a cyclic alkylene group having 1 to 8 carbon atoms. Each of R_{b}^{4a} to R_{b}^{4d} and R_{b}^{6a} to R_{b}^{6c} independently represents a hydrogen atom, or a linear, a branched, or a cyclic alkyl, alkenyl, oxoalkyl, or oxoalkenyl group having 1 to 12 carbon atoms, or an aryl group having 6 to 12 carbon atoms, or an aralkyl or an aryloxoalkyl group having 7 to 12 carbon atoms, wherein a part of or all of their hydrogen atoms may be substituted with an alkoxy group, and R_{b}^{4a} to R_{b}^{4d} and R_{b}^{6a} to R_{b}^{6c} may contain a nitrogen atom, an ether group, an ester group, a hydroxyl group, or a carboxyl group. Any two of R_{b}^{4a} to R_{b}^{4d} or any two of R_{b}⁵ and R_{b}^{6a} to R_{b}^{6c} may be bonded with each other, together with the nitrogen atom to which they are bonded, to form a ring; in this case, each of them independently represents an alkylene group having 3 to 15 carbon atoms or an aromatic heterocyclic ring having in the ring a nitrogen atom shown in the formulae. R_{b}⁵ represents a linear, a branched, or a cyclic alkylene group having 1 to 8 carbon atoms. R_{b}⁷ represents a linear, a branched, or a cyclic alkyl group having 1 to 20 carbon atoms optionally containing a carbonyl group, an ester group, an ether group, or a halogen atom; or an aryl group having 6 to 15 carbon atoms optionally containing a carbonyl group, an ester group, an ether group, a halogen atom, or an alkyl group or a fluorinated alkyl group having 1 to 15 carbon atoms. R_{b}^{8a} and R_{b}^{8b} represent a hydrogen atom, or a linear, a branched, or a cyclic alkyl group having 1 to 15 carbon atoms, wherein R_{b}^{8a} and R_{b}^{8b} may be bonded with each other, together with the carbon atoms to which they are bonded, to form a ring.)

An example of the alkylene group having 1 to 4 carbon atoms of R_{b}² includes a form with one hydrogen atom being pulled-out from a methyl group, an ethyl group, a n-propyl group, an isopropyl group, a n-butyl group, a sec-butyl group, and a tert-butyl group.

An example of the linear, the branched, or the cyclic alkylene group having 1 to 8 carbon atoms of R_{b}³ and R_{b}⁵ includes a form with one hydrogen atom being pulled-out from a methyl group, an ethyl group, a n-propyl group, an isopropyl group, a n-butyl group, a sec-butyl group, a tert-butyl group, a tent-amyl group, a n-pentyl group, a n-hexyl group, a n-heptyl group, a n-octyl group, a cyclopentyl group, a cyclohexyl group, a cyclopentyl methyl group, a cyclopentyl ethyl group, a cyclohexyl methyl group, and a cyclohexyl ethyl group.

In the general formula (ii), an ammonium salt (a cationic part) formed by R_{b}^{4a} to R_{b}^{4d} can be obtained by a neutralization reaction of a corresponding amine compound. In this case, an amine compound such as a primary, a secondary, and a tertiary aliphatic amine, a mixed amine, an aromatic amine, a heterocyclic amine, a nitrogen-containing compound having a carboxy group, a nitrogen-containing compound having a sulfonyl group, a nitrogen-containing compound having a hydroxyl group, a nitrogen-containing compound having a hydroxyphenyl group, an amide, an imide, and a carbamate can be used; and an illustrative example of them includes the compounds described in paragraphs [0146] to [0164] in Japanese Patent Laid-open (Kokai) No. 2008-111103.

R_{b}^{6a} to R_{b}^{6c} and R_{b}⁷ will be described in detail in illustrative examples of the general formula (iii).

An example of the alkyl group having 1 to 15 carbon atoms in R_{b}^{8a} and R_{b}^{8b} includes a methyl group, an ethyl group, a n-propyl group, an isopropyl group, a n-butyl group, a sec-butyl group, a tert-butyl group, a tert-amyl group, a n-pentyl group, a n-hexyl group, a n-heptyl group, a n-octyl group, a n-nonyl group, a n-decyl group, a cyclopentyl group, a cyclohexyl group, a cyclopentyl methyl group, a cyclopentyl ethyl group, a cyclopentyl butyl group, a cyclohexyl methyl group, a cyclohexyl ethyl group, a cyclohexyl butyl group, and an adamantly group.

An illustrative example of the repeating unit shown by the general formula (1) includes the followings, but is not limited to them.

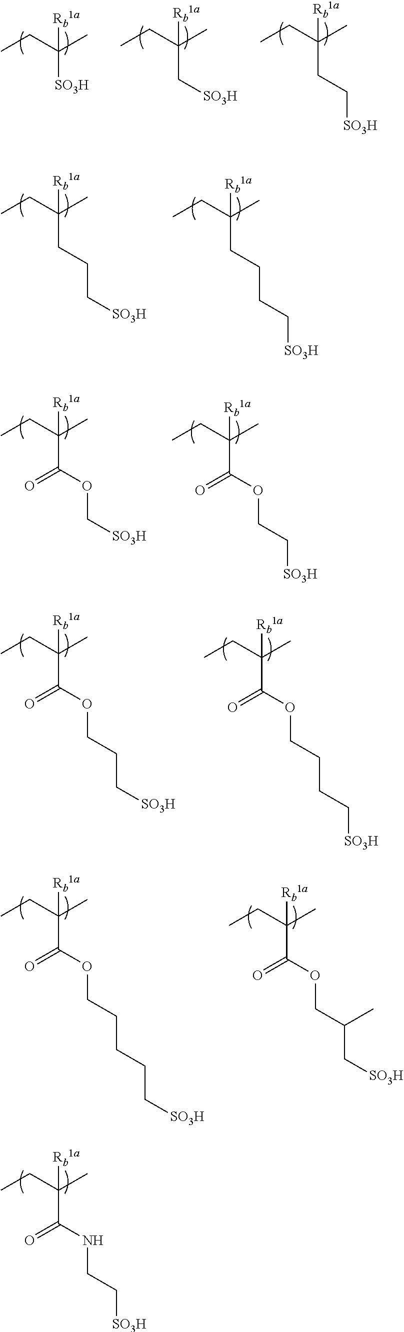

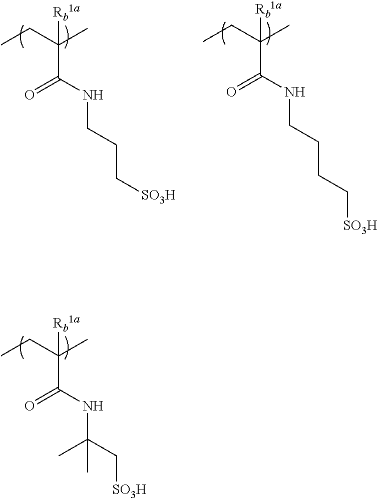

(Wherein, R_{b}^{1a} represents the same as those in the above-mentioned.)

An illustrative example of the repeating unit shown by the general formula (ii) includes the followings, but is not limited to them.

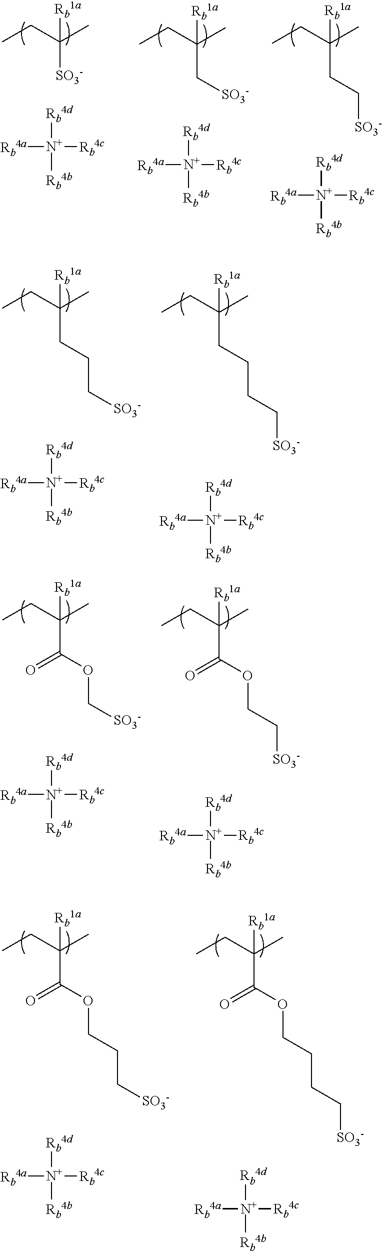

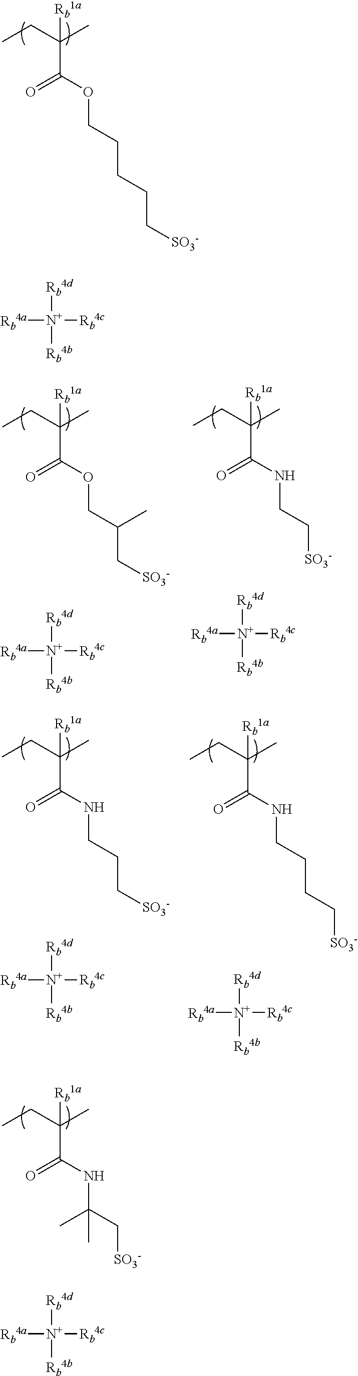

(Wherein, R_{b}^{1a}, and R_{b}^{4a} to R_{b}^{4d} represent the same as those in the above-mentioned.)

An illustrative example of a cationic part of the repeating unit shown by the general formula (iii) includes the followings.

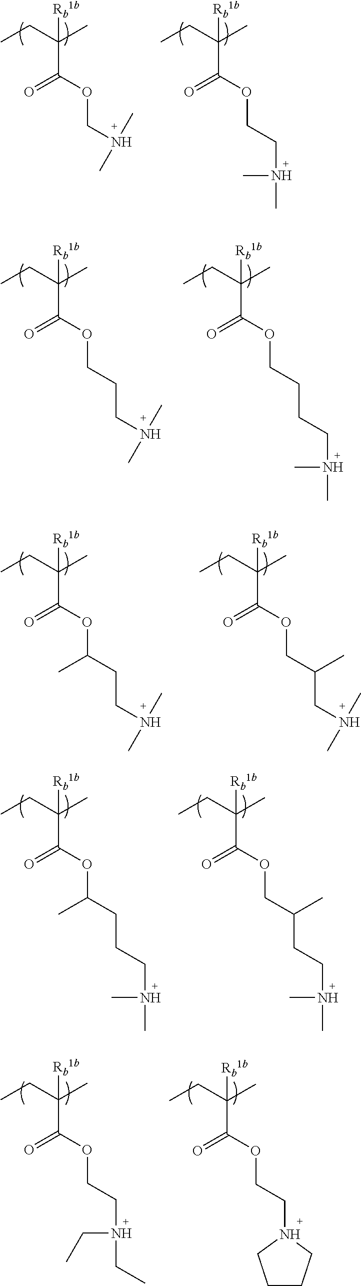

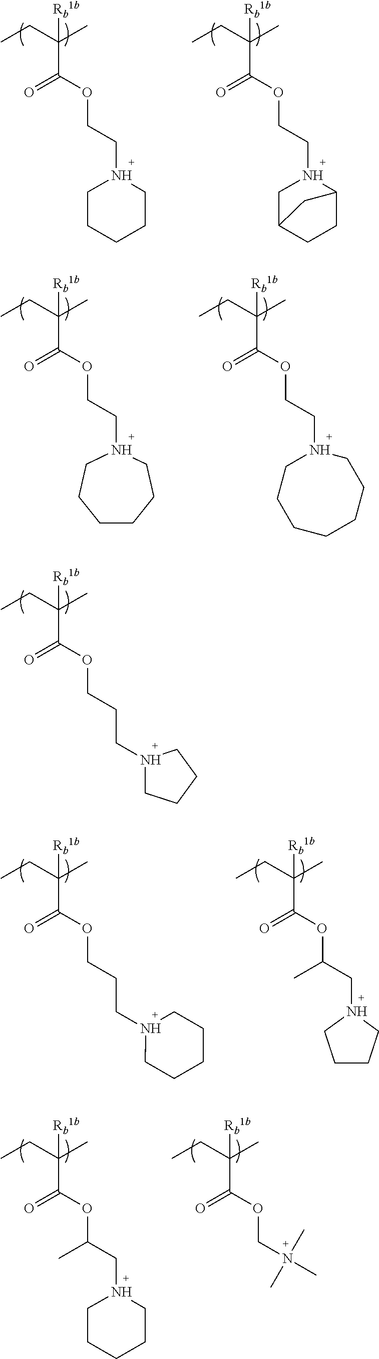

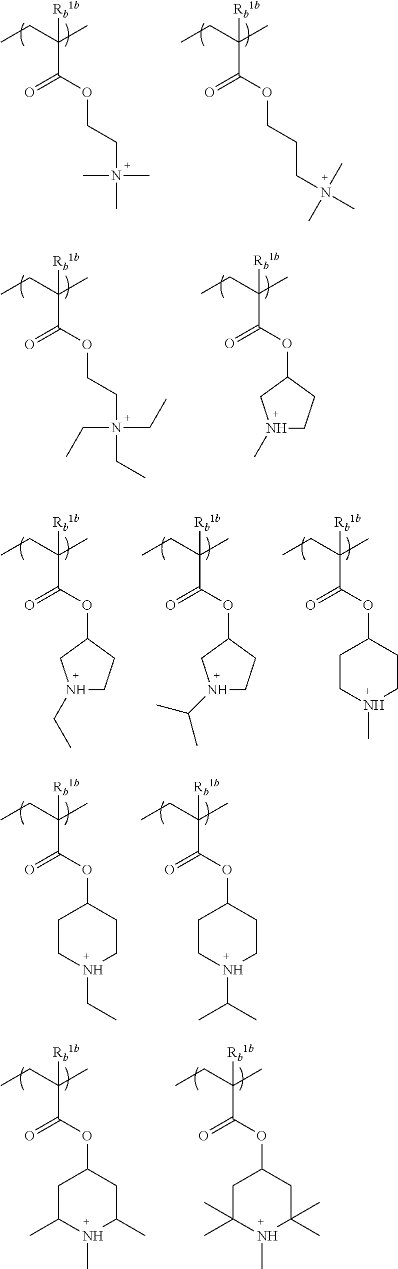

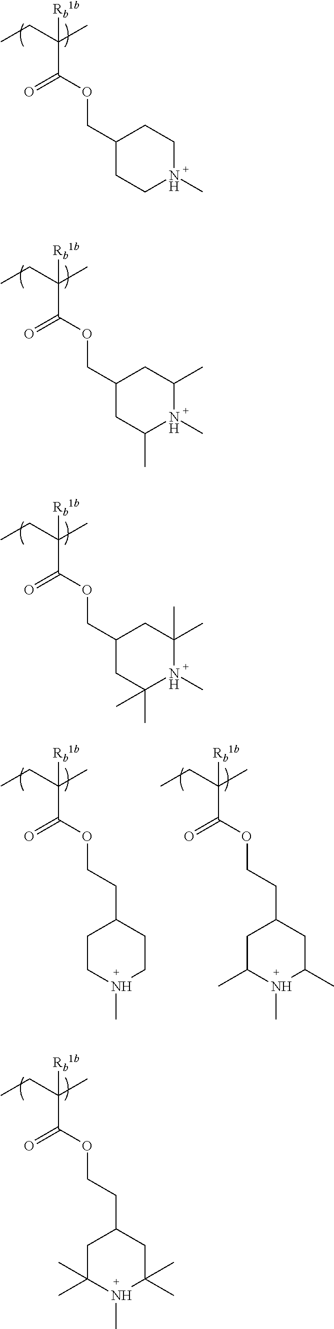

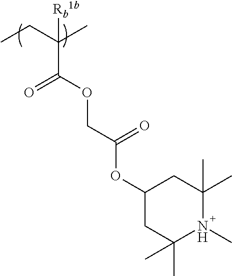

(Wherein, R_{b}^{1b} represent the same as those in the above-mentioned.)

A repeating unit represented by the general formula (iii) is a salt composed of the foregoing cationic moiety and a sulfonate ion. An illustrative example of the sulfonate salt includes a fluoroalkyl sulfonate such as triflate, 1,1,1-trifluoroethane sulfonate, and nonafluorobutane sulfonate; an aryl sulfonate such as tosylate, benzene sulfonate, 4-fluorobenzene sulfonate, 1,2,3,4,5-pentafluorobenzene sulfonate, xylene sulfonic acid, mesitylene sulfonic acid, p-tert-butylbenzene sulfonic acid, naphthalene sulfonic acid, anthracene sulfonic acid, and pyrene sulfonic acid; and an alkyl sulfonate such as mesylate, butane sulfonate, octane sulfonic acid, camphor sulfonic acid, adamantane sulfonic acid, norbornane sulfonic acid, cyclohexyl sulfonic acid, cyclopentane sulfonic acid, cyclobutane sulfonic acid, cyclopropane sulfonic acid, and dodecylbenzene sulfonic acid.

An illustrative example of the repeating unit represented by the general formula (iv) includes the following, but is not limited to them.

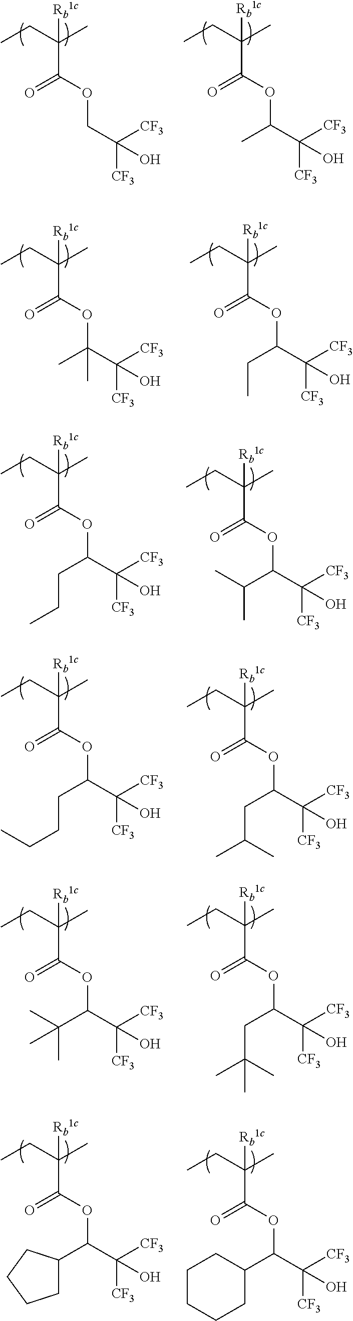

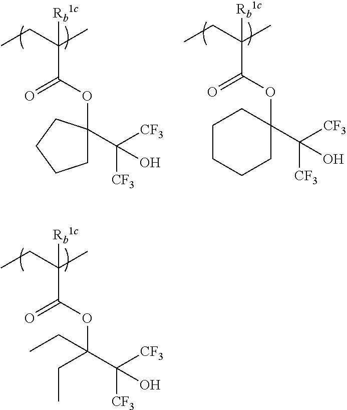

(Wherein, R_{b}^{1c} represents the same as those in the above-mentioned.)

A polymer usable in the resist top coat composition of the present invention (P2) can adequately express the performance by a combination of only the repeating units represented by the general formulae (i) to (iv); but in order to increase water repellent and water sliding properties further and to control an alkaline-solubility and an affinity to a developer, the polymer may be composed of one or in a combination of two or more of the repeating units represented by the foregoing general formulae (3a) to (3e), (4a) to (4e), and (5a) to (5c).

### [Synthesis and Procurement of Polymerizable Monomers]

Polymerization is carried out by using polymerizable monomers corresponding to repeating units represented by the general formulae (1a) to (1c), (2a) to (2i), (3a) to (3e), (4a) to (4e), and (5a) to (5c) when polymers (P1-1) is synthesized, or by using polymerizable monomers corresponding to repeating units represented by the general formulae (1a)′ to (1c), (2a) to (2i), (3a) to (3e), (4a) to (4e), and (5a) to (5c) when polymer (P1-2) is synthesized.

Similarly, polymerization is carried out by using polymerizable monomers corresponding to repeating units represented by the general formulae (i) to (iv), (3a) to (3e), (4a) to (4e), and (5a) to (5c) when polymer (P2) is synthesized. The polymerizable monomers corresponding to the repeating units represented by the general formulae (1a) to (1c), (1a)′ to (1c)′, (2a) to (2i), (3a) to (3e), (4a) to (4e), (5a) to (5c), and (i) to (iv) can be synthesized by the methods or the like heretofore known in literatures (for example, see Japanese Patent Laid-open (Kokai) Nos. 2010-106138, 2007-204385, 2009-29974, 2007-182488, and 2006-152255), or procured from a market.

### [Synthesis of Polymers]

Polymers (P1-1), (P1-2), and (P2) may be synthesized by a general polymerization method such as radical polymerization using an initiator such as 2,2′-azobisbutyronitrile (hereinafter abbreviated as AIBN) and ionic (anionic) polymerization by using an alkyl lithium and the like, wherein these polymerization may be conducted according to a method known to the art. Among them, radical polymerization is preferable for synthesizing polymers (P1-1), (P1-2), and (P2). In this case, polymerization conditions are controlled by the kind and amount of an initiator, temperature, pressure, concentration, solvent, additive, and so on.

The initiator of radical polymerization is not particularly limited, but may be exemplified by an azo compound such as AIBN, 2,2′-azobis(4-methoxy-2,4-dimethylvaleronitrile), 2,2′-azobis(2,4-dimethylvaleronitrile), 2,2′-azobis(2,4,4-trimethylpentane), and 2,2′-azobis(isobutyric acid) dimethyl; a peroxide compound such as tert-butyl peroxypivalate, lauroyl peroxide, benzoyl peroxide, and tert-butyl peroxylaurate; a water-soluble polymerization initiator such as potassium persulfate; a redox initiator such as a combination of a peroxide such as potassium persulfate and hydrogen peroxide with a reducing agent such as sodium sulfite; and the like. Amount of the polymerization initiator is variable according to its kind, polymerization conditions, and the like; but 0.001 to 10% by mol, in particular 0.01 to 6% by mol, relative to total amount of the monomers to be polymerized, is usually used.

When polymers (P1-1), (P1-2), and (P2) are synthesized, a chain transfer agent heretofore known in the art such as dodecyl mercaptans and 2-mercapto ethanol may be used to control their molecular weights. In this case, amount of the chain transfer agent is preferably 0.01 to 10% by mol relative to total mol of the monomers to be polymerized.

When polymer (P1-1) is synthesized, polymerizable monomers corresponding to repeating units represented by the general formulae (1a), (1b-1), (1c), (2a) to (2i), (3a) to (3e), (4a) to (4e), and (5a) to (5c) are mixed, and then polymerization is carried out by adding the polymerization initiator and the chain transfer agent as mentioned above into the obtained mixture.

In polymer (P1-1), if total mol of a monomer corresponding to the unit represented by the general formula (1a) is made Ulf, total mol of a monomer corresponding to the unit represented by the general formula (1b-1) is made U12, total mol of a monomer corresponding to the unit represented by the general formula (1c) (including (1c^{s})) is made U13, and

total mol of monomers corresponding to entire repeating units contained in polymer (P1-1) is made U1, they are in the following relationships:

0<U11/U1<1, or preferably 0.5≦U11/U1≦0.95,

0<U12/U1<1, or preferably 0.05≦U12/U1≦0.5,

0<U13/U1<1, or preferably 0.01≦U13/U1≦0.3, and

0<(U11+U12+U13)/U1≦1, or preferably

0.6≦(U11+U12+U13)/U1≦1. And further,

if total mol of monomers corresponding to the units represented by the general formulae (2a) to (2i) is made U14,
total mol of monomers corresponding to the units represented by the general formulae (3a) to (3e), (4a) to (4e), and (5a) to (5c) is made U15, and

U0=U11+U12+U13+U14+U15,

they are in the following relationships:

0<(U11+U12+U13)/U0≦1, or preferably

0.6≦(U11+U12+U13)/U0≦1,

0≦U14/U0<1, or preferably 0≦U14/U0≦0.2, and

0≦U15/U0<1, or preferably 0≦U15/U0≦0.2.

Similarly, when polymer (P1-2) is synthesized, polymerizable monomers corresponding to repeating units represented by the general formulae (1a)′, (1b-2), (1c)′, (2a) to (2i), (3a) to (3e), (4a) to (4e), and (5a) to (5c) are mixed, and then polymerization is carried out by adding the polymerization initiator and the chain transfer agent as mentioned above into the obtained mixture.

In polymer (P1-2), if total mol of a monomer corresponding to the unit represented by the general formula (1a)′ is made U11′, total mol of a monomer corresponding to the unit represented by the general formula (1b-2) is made U12′, total mol of a monomer corresponding to the unit represented by the general formula (1c)′ (including (1c^{s})′) is made U13, and

total mol of monomers corresponding to entire repeating units contained in polymer (P1-2) is made U11, they are in the following relationships:

0<U11′/U1′<1, or preferably 0.5≦U11′/U1′≦0.95,

0<U12′/U1′<1, or preferably 0.05≦U12′/U1′≦0.5,

0<U13′/U1′<1, or preferably 0.01≦U13′/U1′≦0.3, and

0<(U11′+U12′+U13′)/U1′≦1, or preferably 0.6≦(U11′+U12′+U13′)/U1′≦1. And further, if total mol of monomers corresponding to the units represented by the general formulae (2a) to (2i) is made U14′,

total mol of monomers corresponding to the units represented by the general formulae (3a) to (3e), (4a) to (4e), and (5a) to (5c) is made U15′, and

U0′=U11′+U12′+U13′+U14′+U15°,

they are in the following relationships:

0<(U11′+U12′+U13′)/U0≦1, or preferably

0.6≦(U11′+U12′+U13′)/U0′≦1,

U≦U14′/U0′<1, or preferably 0≦U14′/U0′≦0.2, and

0≦U15′/U0′<1, or preferably 0≦U15′/U0′≦0.2.

When polymer (P2) is synthesized, polymerizable monomers corresponding to repeating units represented by the general formulae (i) to (iv), (3a) to (3e), (4a) to (4e), and (5a) to (5c) are mixed, and then polymerization is carried out by adding the polymerization initiator and the chain transfer agent as mentioned above into the obtained mixture.

In polymer (P2),

if total mol of monomers corresponding to the units represented by the general formulae (i) and (ii) is made U21,
total mol of a monomer corresponding to the unit represented by the general formula (iii) is made U22,
total mol of a monomer corresponding to the unit represented by the general formula (iv) is made U23, and

U2=U21+U22+U23,

they are in the following relationships:

0≦U21/U21, or preferably 0≦U21/U2≦0.4,

0≦U22/U2≦1, or preferably 0≦U22/U2≦0.4, and

0<U23/U2<1, or preferably 0.5≦U23/U2<1. And further, if total mol of monomers corresponding to the units represented by the general formulae (2a) to (2i) is made U24,
total mol of monomers corresponding to the units represented by the general formulae (3a) to (3e), (4a) to (4e), and (5a) to (5c) is made U25, and

U=U21+U22+U23+U24+U25,

they are in the following relationships:

0<(U21+U22U23)/U≦1, or preferably 0.6≦(U21+U22+U23)/U≦1,

0≦U24/U<1, or preferably 0≦U24/U≦0.3, and

0≦U25/U<1, or preferably 0≦U25/U≦0.2.

When polymerization is carried out, a solvent may be used if necessary. A solvent for polymerization is preferably the one not inhibiting the polymerization. A typical example of the usable solvent includes an ester such as ethyl acetate, n-butyl acetate, and γ-butyrolactone; a ketone such as acetone, methyl ethyl ketone, and methyl isobutyl ketone; an aliphatic or an aromatic hydrocarbon such as toluene, xylene, and cyclohexane; an alcohol such as isopropyl alcohol and ethylene glycol monomethyl ether; and an etheric solvent such as diethyl ether, dioxane, and tetrahydrofurane. These solvent may be used singly or in a combination of two or more kinds of them. Amount of the solvent for polymerization is variable, as appropriate, according to polymerization conditions such as an intended degree of polymerization (molecular weight), an added amount of an initiator, and polymerization temperature; but usually the solvent is used such that concentration of monomers to be polymerized may be 0.1 to 95% by mass, or particularly 5 to 90% by mass.

Temperature of a polymerization reaction is variable, as appropriate, according to kind of the polymerization initiator or boiling point of the solvent, but preferably 20 to 200° C. in general, or particularly 50 to 140° C. A reaction vessel used in the polymerization is not particularly limited.

Any method heretofore known in the art for removing an organic solvent or water present as the medium from a solution or a disperse solution of an obtained polymer can be used; an example of the method includes reprecipitation filtration and distillation by heating under vacuum.

In the case of polymers (P1-1), (P1-2), and (P2), when a weight-average molecular weight (Mw) is too small, mixing with a resist composition and dissolution into water take place easily. When a weight-average molecular weight is too large, there appears a problem in film formation after spin-coating and there occurs decrease of solubility in an alkaline solution in some cases. In view of these, the weight-average molecular weight based on polystyrene by a gel permeation chromatography (GPC) is 1,000 to 500,000, or preferably 2,000 to 30,000.

In polymers (P1-1), (P1-2), and (P2), R¹² of the general formula (1b-2), R³³ of the general formula (3c), and R⁴³ of the general formula (4c) may be introduced by a post-protection reaction. Namely, a monomer whose R¹², R³³, or R⁴³ is hydrogen is polymerized to synthesize a polymer in advance; and then a part of or all of a hydroxyl group in the polymer obtained is displaced with R¹², R³³, or R⁴³ by the post-protection reaction as shown below.

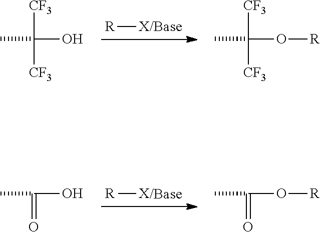

(Wherein, R represents R¹², R³³, and R⁴³. X represents chlorine, bromine, and iodine.)

In the post-protection reaction, 1 to 2 equivalents of a base relative to an intended displacement rate of the hydroxyl group is reacted with a polymer, and then 1 to 2 equivalents of R—X relative to the base is reacted to obtain an intended post-protection polymer.

In the post-protection reaction, a solvent selected from a hydrocarbon such as benzene and toluene, and an ether such as dibutyl ether, diethylene glycol diethyl ether, diethylene glycol dimethyl ether, tetrahydrofurane, and 1,4-dioxane may be used singly or as a mixture of two or more kinds of them. A base such as sodium hydride, n-butyl lithium, lithium diisopropylamide, triethylamine, and pyridine may be used, though the base is not limited to them.

In polymers (P1-1), (P1-2), and (P2), an ammonium salt in a repeating unit represented by the general formulae (1c^{s}) and (ii) can be obtained by a neutralization reaction between a sulfo group and a corresponding amine or an ion-exchange reaction with an ammonium salt represented by the following general formulae.

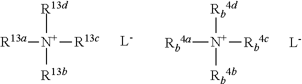

(Wherein, R^{13a} to R^{13d} and R_{b}^{4a} to R_{b}^{4d} represent the same as those in the above-mentioned; and L⁻ represents OH⁻, Cl⁻, Br⁻, I⁻, R_{b}⁹CO₂⁻, or NO₃⁻. R_{b}⁹ represents a hydrogen atom or a monovelent organic group.)

When a repeating unit represented by the general formula (1c) or (ii) is introduced into polymers (PI-1), (P1-2), and (P2), the forgoing neutralization reaction and ion-exchange reaction can be done in the stage of a monomer or after polymer synthesis. In the case that the foregoing reaction is carried out after polymer synthesis, if amount of added amine is too small, the amine salt cannot be formed uniformly in a polymer unit, thereby occasionally causing a bridge defect locally upon pattern formation. In order to avoid such defect, it is preferable to carry out the neutralization reaction or the ion-exchange reaction in the stage of monomer and thereafter to carry out polymerization by using the monomer having a uniformly distributed ammonium sulfonate salt.

In the case that a repeating unit represented by the general formula (iii) is introduced into polymer (P2), a polymer containing a tertiary or less ammonium salt of an amine of equal to or less than tertiary can be obtained by a neutralization reaction of a (meth)acrylate having an amino group in its side chain with a corresponding sulfonic acid. A polymer containing a quaternary ammonium salt can be obtained by an ion-exchange reaction similar to the forgoing. Similarly to the repeating unit represented by the general formula (ii), the foregoing neutralization reaction and ion-exchange reaction can be carried out in the stage of monomer as well as after polymer synthesis.

In a repeating unit represented by the general formula (ii) of polymer (P2), a neutralized amount of a sulfo group in the entire polymer with an amine compound may be under-equivalent in the amine while over-equivalent in the sulfonic acid residue, or on the contrary, over-equivalent in the amine. When the sulfonic acid residue is present, upon combination with a photoresist, it has an effect to inhibit a bridging among resist patterns after development; on the other hand, when the amine is present over-equivalent, it has an effect to improve rectangularity of a resist pattern. Based on these effects, amounts of the sulfo group and the amine may be appropriately controlled with observing a resist pattern after development. The same can be applied to a repeating unit represented by the general formula (iii).

### [Preparation of Resist Top Coat Composition]

In the resist top coat composition of the present invention, the repeating units represented by the general formulae (1a) and (1a)′ in polymers (P1-1) and (P1-2) not only exhibit solubility into an alkaline developer but also express excellent performance in water repellent and water sliding properties. Performance necessary as a resist top coat composition with regard to water repellent and water sliding properties, lipophilicity, and decomposition properties by an acid and a hydrolysis can be controlled by manipulating the side chain structure of the general formulae (X), (Y), (Z), and the like in the repeating units represented by the general formulae (1b-1) and (1b-2). In addition, in polymers (P1-1) and (P1-2), a resist-top coat composition giving an excellent pattern profile with fewer development defects can be realized by combining the repeating units represented by the general formulae (1c) and (1c)′.

Each of polymers (P1-1) and (P1-2) can express excellent performance as a resist top coat composition by itself; but as mentioned above, they can be used as a blend with polymer (P2). In the case that polymer (22) contains a hydrophilic ammonium sulfonate salt in its repeating unit, when polymer (P1-1) or polymer (P1-2) is used as a mixture with polymer (P2), a phase separation takes place between these two polymers upon spin-coating, thereby localizing polymer (P1-1) or polymer (P1-2) having excellent water repellent and water sliding properties at a upper layer of the top coat and a hydrophilic polymer (P2) over the resist film (at a lower layer of the top coat). As a result, a resist surface becomes hydrophilic after development so that a blob defect can be suppressed.

In the case that a polymer containing only a sulfo group is used as the resist top coat composition, a part of a quencher in a resist film migrates to the top coat layer. Migration of the quencher leads to decrease in quencher concentration on the resist outer-most surface thereby causing film loss of a resist pattern after development; as a result, there is a risk of decrease in an etching resistance. On the other hand, polymer (P2) has an ammonium sulfonate salt in the top coat layer thereby inhibiting migration of the quencher as mentioned above; and thus, a rectangular resist pattern can be obtained.

In the case that polymer (P1-1) or polymer (P1-2) is used as a blend with polymer (P2), the mixing ratio is arbitrary; and a mass ratio of polymer (P1-1) or polymer (P1-2) to total resin can be made in the range of 5 to 95%, preferably 20 to 93%, or more preferably 30 to 90%.

In the resist top coat composition of the present invention, in addition to polymer (P1-1) or polymer (P1-2), polymer (P2) may be preferably used; but in order to change dynamic physical properties of the film, thermal properties, alkaline-solubility, water repellent and water sliding properties, and other properties, other polymer can be mixed to it. In this case, an amount of the polymer to be mixed is not particularly limited; and a heretofore known polymer and the like used for a resist top coat can be mixed in arbitrary amount range.

It is preferable that a resist top coat composition of the present invention be used by dissolving the polymer in a solvent. In this case, in view of film formation by a spin coating method, it is preferable to use a solvent such that concentration of the polymer in it may be 0.1 to 20% by mass, in particular, 0.5 to 10% by mass.

A solvent to be used is not particularly limited, but a solvent not dissolving the resist layer is preferably used. An example of the solvent not dissolving the resist layer includes a higher alcohol having 4 or more of carbon atoms, toluene, xylene, anisole, hexane, cyclohexane, decane, a non-polar solvent such as an ether compound, and the like. In particular, a higher alcohol having 4 or more of carbon atoms and an ether compound having 8 to 12 carbon atoms are preferably used; and specifically, 1-butyl alcohol, 2-butyl alcohol, isobutyl alcohol, tert-butyl alcohol, 1-pentanol, 2-pentanol, 3-pentanol, tert-amyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-diethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, diisopropyl ether, diisobutyl ether, diisopentyl ether, di-n-pentyl ether, methyl cyclopentyl ether, methyl cyclohexyl ether, di-n-butyl ether, di-sec-butyl ether, diisopentyl ether, di-sec-pentyl ether, di-t-amyl ether, di-n-hexyl ether, and the like can be mentioned, wherein they may be used singly or as a mixture of two or more of them, though not limiting to them.

On the other hand, a fluorinated solvent can be used preferably because it does not dissolve the resist layer. An example of the fluorine-substituted solvent includes 2-fluoroanisole, 3-fluoroanisole, 4-fluoroanisole, 2,3-difluoroanisole, 2,4-difluoroanisole, 2,5-difluoroanisole, 5,8-difluoro-1,4-benzodioxane, 2,3-difluorobenzyl alcohol, 1,3-difluoro-2-propanol, 2′,4′-difluoropropiophenone, 2,4-difluorotoluene, trifluoroacetaldehyde ethyl hemiacetal, trifluoroacetamide, trifluoroethanol, 2,2,2-trifluoroethyl butyrate, ethyl hepatafluorobutyrate, ethyl hepatafluorobutyl acetate, ethyl hexafluoroglutaryl methyl, ethyl-3-hydroxy-4,4,4-trifluorobutyrate, ethyl-2-methyl-4,4,4-trifluoroacetoacetate, ethyl pentafluorobenzoate, ethyl pentafluoropropionate, ethyl pentafluoropropynyl acetate, ethyl perfluorooctanoate, ethyl-4,4,4-trifluoroacetoacetate, ethyl-4,4,4-trifluorobutyrate, ethyl-4,4,4-trifluorocrotonate, ethyl trifluorosulfonate, ethyl-3-(trifluoromethyl) butyrate, ethyl trifluoropilvate, S-ethyl trifluoroacetate, fluorocyclohexane, 2,2,3,3,4,4,4-hepatafluoro-1-butanol, 1,1,1,2,2,3,3-heptafluoro-7,7-dimethyl-4,6-octanedione, 1,1,1,3,5,5,5-heptafluoropentane-2,4-dione, 3,3,4,4,5,5,5-heptafuloro-2-pentanol, 3,3,4,4,5,5,5-heptafluoro-2-pentanone, isopropyl 4,4,4-trifluoroacetoacetate, methyl perfluorodenanoate, methyl perfluoro(2-methyl-3-oxahexanoate), methyl perfluorononanoate, methyl perfluorooctanoate, methyl 2,3,3,3-tetrafluoropropionate, methyl trifluoroacetoacetate, 1,1,1,2,2,6,6,6-octafluoro-2,4-hexanedione, 2,2,3,3,4,4,5,5-octafluoro-1-pentanol, 1H,1H,2H,2H-perfluoro-1-decanol, perfluoro(2,5-dimethyl-3,6-dioxaneanionic)acid methyl ester, 2H-perfluoro-5-methyl-3,6-dioxanonane, 1H,1H,2H,3H,3H-perfluorononane-1,2-diol, 1H,1H,9H-perfluoro-1-nonanol, 1H,1H-perfluorooctanol, 1H,1H,2H,2H-perfluorooctanol, 2H-perfluoro-5,8,11,14-tetramethyl-3,6,9,12,15-pentaoxaoctadecane, perfluorotributyl amine, perfluorotrihexyl amine, perfluoro-2,5,8-trimethyl-3,6,9-trioxadodecanoic acid methyl ester, perfluorotripentyl amine, perfluorotripropyl amine, 1H,1H,2H,3H,3H-perfluoroundecane-1,2-diol, trifluorobutanol, 1,1,1-trifluoro-5-methyl-2,4-hexanedione, 1,1,1-trifluoro-2-propanol, 3,3,3-trifluoro-1-propanol, 1,1,1-trifluoro-2-propyl acetate, perfluorobutyl tetrahydrofurane, perfluoro(butyltetrahydrofurane), perfluorodecaline, perfluoro(1,2-dimethylcyclohexane), perfluoro(1,3-dimethylcyclohexane), propylene glycol trifluoromethyl ether acetate, propylene glycol methyl ether trifluoromethyl acetate, butyl trifluoromethylacetate, methyl 3-trifluoromethoxypropionate, perfluorocyclohexanone, propylene glycol trifluoromethyl ether, butyl trifluoroacetate, 1,1,1-trifluoro-5,5-dimethyl-2,4-hexanedione, 1,1,1,3,3,3-hexafluoro-2-propanol, 1,1,1,3,3,3-hexafluoro-2-methyl-2-propanol, 2,2,3,4,4,4-hexafluoro-1-butanol, 2-trifluoromethyl—2-propanol, 2,2,3,3-tetrafluoro-1-propanol, 3,3,3-trifluoro-1-propanol, and 4,4,4-trifluoro-1-butanol; and they may be used singly or as a mixture of two or more of them, though not limited them.

In the resist top coat composition of the present invention, performance improvement such as adjustment of a pattern profile may be conducted by a basic compound. A polymer used in the resist top coat composition of the present invention contains an acidic hydroxyl group in its repeating unit, and thus there is a chance that a part of a quencher in a resist film may migrate to a top coat layer. As mentioned above, migration of a quencher causes decrease of a quencher concentration on the outermost resist surface thereby leading to film loss of a resist pattern after development. In order to avoid such quencher migration, a basic compound may be added in the resist top coat composition in advance so that deterioration of a pattern profile can be prevented from occurring.

Here, a nitrogen-containing organic compound is most preferable as the basic compound, wherein it can be used singly or as a mixture of two or more of the nitrogen-containing organic compounds. An example of the nitrogen-containing organic compound includes a primary, a secondary, and a tertiary aliphatic amine, a mixed amine, an aromatic amine, a heterocyclic amine, a nitrogen-containing compound having a carboxylic group, a nitrogen-containing compound having a sulfonyl group, a nitrogen-containing compound having a hydroxyl group, a nitrogen-containing compound having a hydroxyphenyl group, an amide, an imide, and a carbamate; and an illustrative example of them includes the compounds described in paragraphs [0149] to [0163] in Japanese Patent Laid-open (Kokai) No. 2008-111103. An amount of the basic compound is preferably in the range of 0.001 to 2 parts by mass, in particular in the range of 0.01 to 1 part by mass, relative to 100 parts by mass of a base resin.

### [Patterning Process]

The patterning process of the present invention preferably includes at least (1) a step of forming a photoresist film over a substrate, (2) a step of forming a resist top coat on the photoresist film by using the resist top coat composition of the present invention, (3) a step of exposure, and (4) a step of developing by using a developer.

In forming a resist top coat, the resist top coat composition solution is spin-coated on a photoresist film obtained after prebaking, and the composition is pre-baked on a hot plate at 50 to 150° C. for 1 to 10 minutes, preferably 70 to 140° C. for 1 to 5 minutes to form a resist top coat. The film thickness of the resist top coat is preferably 10 to 500 nm.

The dispensing amount of the resist top coat composition can be reduced by spin-coating the resist top coat composition on a resist film whose surface is applied in advance with a solvent. In this case, spin-coating method, and paper prime method, and the like, can be used for applying the surface of the resist. The spin-coating method is typically used. The solvent to be used can be selected from above-mentioned solvent of higher alcohol, ether type, and fluorine type, which do not solve the resist.

At the step of exposuring, a mask for forming an intented pattern is placed over the photoresist film, subsequently high energy beam such as deep-ultraviolet, excimer laser, X beam, and an electron beam is irradiated. The exposure dose is 1 to 200 mJ/cm², preferably 10 to 100 mJ/cm². Exposure is preferably conducted by an immersion method in which a space between the resist top coat and a projection lens is immersed with a liquid, but not limited to this method. Dry-exposure under atmosphere or nitrogen atmosphere and exposure under vacuum such as EB and EUV may be applied. In the case of immersion exposure, light-source with 250 to 180 nm wavelength is preferable, and water is preferably used as a liquid inserted between the projection lens and the top coat.

In order to prevent water from coming around the back surface of the wafer and from leaching from the substrate, presence or absence of cleaning of edge and back surface of the wafer, and further cleaning method is important. For example, solvent can be vaporized by baking the resist top composition in the range of 40 to 130° C. for 10 to 300 seconds after spin coating of the resist top coat. It is noted that edge-cleaning, which is done upon resist film-forming in the case of dry exposure, is not preferred in some cases, because water remains at the edge portion of the hydrophilic substrate. Thus, edge cleaning is not conducted upon spin-coating of the resist top coat in some cases.

A post exposure bake (PEB) is conducted after the exposure on a hot plate at 60 to 150° C. for 1 to 5 minutes, preferably 80 to 140° C. for 1 to 3 minutes. In conducting PEB, if water remains on the resist top coat, there is a possibility that water passes through the resist top coat during PEB. As a result, pattern can not be formed in some cases because an acid in the resist film is absorbed. In order to prevent such a case, it is necessary for water on the top coat to be removed completely before PEE. This method includes: spin dry method; method of purging to the surface of the top coat by dry air and hydrogen; and method of optimization such as shape of water recovering-nozzle and process of water recovering. Furthermore, design and usage of a material having excellent water repellent and water sliding properties like the top coat composition of the present invention is effective to separate water.

Further, after conducting PEB, development is carried out in a developer solution such as a alkaline solution of tetramethyl ammonium hydroxide (TMAH) aqueous solution with the concentration of 0.1 to 5% by mass or preferably 2 to 3% by mass and the time for 10 to 300 seconds or preferably for 0.5 to 2 minutes by such a usual method as a dip method, a puddle method, and a spray method. Tetramethyl ammonium hydroxide aqueous solution with the concentration of 2.38% has been typically used for an alkaline developer. In the case of using the resist top coat composition of the present invention, the resist top coat can be delaminated at the same time as development because the top coat composition itself is alkaline.

In a patterning process by using the resist top coat composition of the present invention, a resist composition to form an underlayer photoresist film is not particularly limited. Both a positive type and a negative type of a resist composition may be used. Further, both a usual monolayer resist composition of hydrocarbon and a usual bilayer (multilayer) resist composition containing a silicon atom and the like may be used. Film formation may be conducted by a spin-coating method, for example. In order to reduce a dispensing amount of a photoresist film composition in spin-coating, it is preferable that the photoresist film composition be dispensed by spin-coating to a substrate which is applied in advance with a photoresist solvent or a solution mixed with a photoresist solvent.

In a resist composition used in a KrF exposure, poly(hydroxystyrene) or a hydroxystyrene-(meth)acrylate copolymer, a part or all of whose hydrogens in their hydroxyl group or carboxyl group are substituted with an acid labile group, is preferably used.

In a resist composition used in an ArF exposure, a base resin having a structure not containing an aromatic ring is preferable; specifically a copolymer of an (meth)acrylic acid derivative, an alternate copolymer of a norbornene derivative and maleic anhydride, a copolymer of a norbornene derivative, maleic anhydride, and a (meth)acrylic acid derivative, an alternate copolymer of a tetracyclododecene derivative and maleic anhydride, a copolymer of a tetracyclododecene derivative, maleic anhydride, and a (meth)acrylic acid derivative, an alternate copolymer of a norbornene derivative and a maleimide derivative, a copolymer of a norbornene derivative, a maleimide derivative, and a (meth)acrylic acid derivative, an alternate copolymer of a tetracyclododecene derivative and a maleimide derivative, a copolymer of a tetracyclododecene derivative, a maleimide derivative, and a (meth)acrylic acid derivative, a polynorbornene, and a polymer formed by methathesis ring-opening may be used singly or as a mixture of two or more of these polymers.

A composition having an aromatic ring in a repeating unit has an absorption at 193 nm wavelength so that it could not be used in an ArF resist composition in the beginning; but its use has been studied as a resist film moves toward thinner thereby leading to decrease in influence of the absorption. In addition, because a reflection from a substrate by a slant incident light increases when NA of a projection lens is more than one, a proposal is made to aggressively utilize an aromatic ring having the absorption thereby suppressing the reflection from a substrate. In this case, a copolymer with hydroxyvinyl naphthalene, a methacrylate having a naphthalene or a naphthol skeleton in its side chain, a fluorinated hydroxystyrene, a fluoroalkyl hydroxystyrene, a fluorinated styrene, a fluoroalkyl styrene, hexafluoroisopropanol styrene, hexafluoroisopropanol indene, and the like may be used.

The resist top coat composition of the present invention may also be used in a patterning process for mask blanks. After a photoresist is applied on mask blanks substrate such as SiO₂, Cr, CrO, CrN, and MoSi, a resist top coat is formed over it by using the resist top coat composition of the present invention. At this time, a three-layered structure may be formed by forming a SOG film and an organic underlayer film between a photoresist and a blanks substrate. A pattern is formed by conducting, after formation of a resist top coat, exposure by an electron beam under vacuum by using an electron beam drawing instrument, a post-exposure bake (PEB) after the exposure, and then development by an alkaline developer for 10 to 300 seconds.

In a resist composition for mask blanks, a novolak, hydroxystyrene, and the like are mainly used as a base resin. A resin whose alkaline-soluble hydroxyl group is substituted with an acid labile group is used as a positive type, while a resin added with a crosslinking agent is used as a negative type. Specifically, a polymer obtained by copolymerization of hydroxystyrene with an (meth)acryl derivative, styrene, vinyl naphthalene, vinyl anthracene, vinyl pyrene, hydroxyvinyl naphthalene, hydroxyvinyl anthracene, indene, hydroxy indene, acenaphthylene, a norbornadiene, cumaron, chromone, or the like is preferably used.

### EXAMPLES

Hereinbelow, the present invention will be specifically explained by showing Examples and Comparative Examples; but the present invention is not limited to the following Examples. Here, “GPC” in Examples means a gel permeation chromatography, wherein a weight-average molecular weight (Mw) and a number-average molecular weight (Mn) were measured by GPC as the polystyrene equivalent. Further, Me in the following Examples means a methyl group.

### [Synthesis Examples of Polymers]

Structural formulae of polymerizable monomers (Monomers 1 to 14) used in Synthesis Examples of Polymers are shown below.

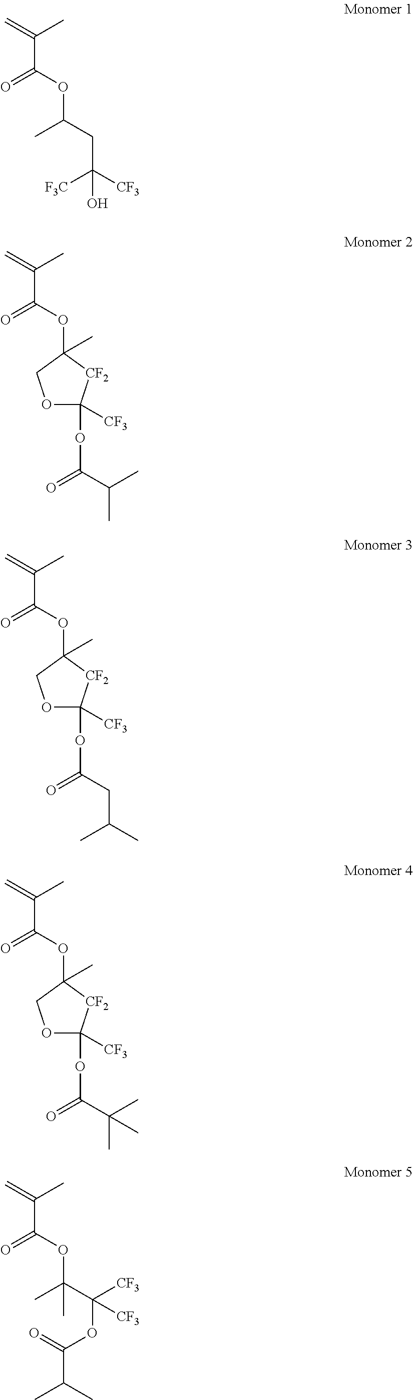

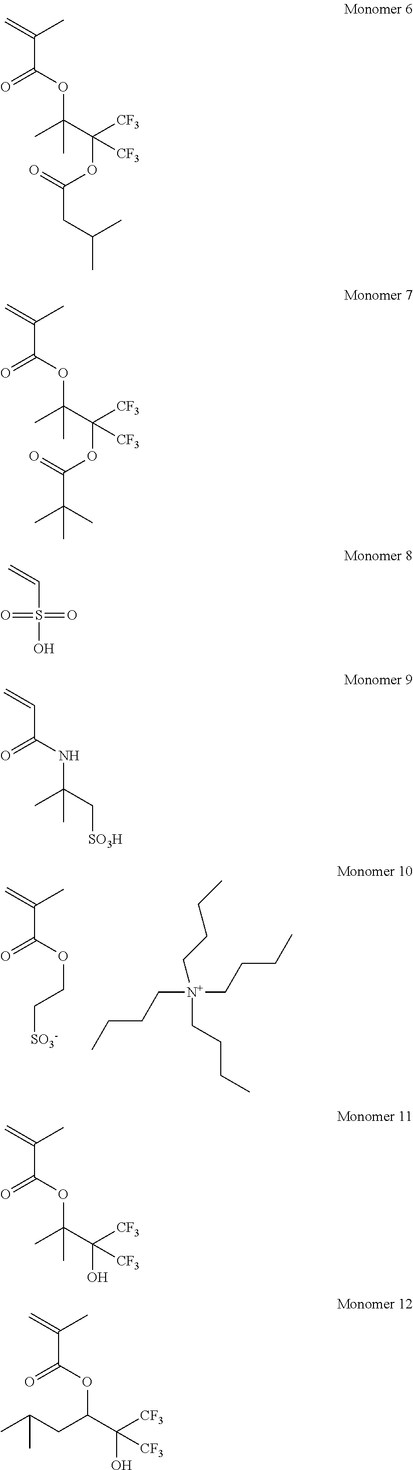

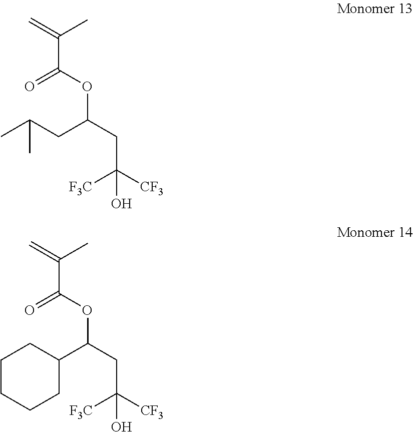

### Polymer Synthesis Example 1

### Copolymerization of Monomer 1, Monomer 2, and Monomer 8 (85/12.5/2.5)

Into a flask under a nitrogen atmosphere, 86.39 g of Monomer 1, 15.12 g of Monomer 2, 0.93 g of Monomer 8, 6.19 g of dimethyl 2,2′-azobis(isobutyric acid), and 200 g of 2-propanol were added to prepare a monomer solution with the solution temperature of 20 to 25° C. Into another flask under a nitrogen atmosphere, 100 g of 2-propanol was added, and then heated to 80° C. with stirring; thereafter, into it, the above-mentioned monomer solution was added drop-wise over 3 hours. After completion of the addition, the resulting polymerization solution was stirred for 3 hours with maintaining the temperature at 80° C., and then cooled to room temperature after completion of aging. The polymerization solution was concentrated to total mass of 200 g by an evaporator, and then 200 g of methanol and 800 g of hexane were added; and the resulting mixture was stirred for 15 minutes. After stirring was stopped, into a lower layer taken out by layer separation, 200 g of methanol and 800 g of hexane were added, and then the resulting mixture was stirred for 15 minutes. A lower layer was taken out by layer separation and then added with 700 g of 4-methyl-2-pentanol; and thereafter the resulting mixture was concentrated by an evaporator until total mass of the polymer solution reached 650 g to obtain a solution of 4-methyl-2-pentanol containing an intended polymer (Polymer 1).

Solvents of the polymer solution was evaporated, and then weight of the residue was measured; it was determined that concentration of the solution be 11.7% by weight (yield of 76.1%). Composition of the resin was analyzed by ¹H-NMR and ¹⁹F-NMR, showing that composition ratio of Monomer 1/Monomer 2/Monomer 8 be 86/12.3/1.7% by mol. A weight-average molecular weight (Mw) obtained by GPC was 6,600 (Mw/Mn=1.44).

### Polymer Synthesis Examples 2 to 12

The foregoing polymerizable monomers (Monomers 1 to 14) were charged with the compositions shown in the following Tables 1 to 5; and Polymers 2 to 12 shown below were synthesized by a similar manner to those in the synthesis of Polymer 1.

TABLE 1

| | | | | | | | Weight- | |
|---|---|---|---|---|---|---|---|---|
| | | | | | | | average | |
| | | | | | | | molecular | |
| | Monomer | Monomer | Monomer | Monomer | Monomer | Yield | weight | Dispersity |
| | 1 | 2 | 3 | 4 | 8 | (%) | (Mw) | (Mw/Mn) |
| Polymer 1 | 85 | 12.5 | | | 2.5 | 76.1 | 6,600 | 1.44 |
| Polymer 2 | 85 | | 12.5 | | 2.5 | 74.5 | 6,700 | 1.43 |
| Polymer 3 | 85 | | | 12.5 | 2.5 | 73.5 | 6,800 | 1.45 |

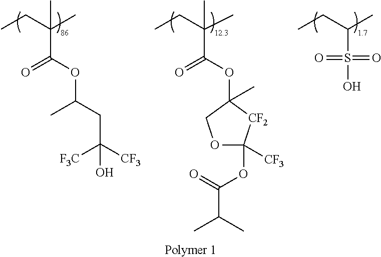

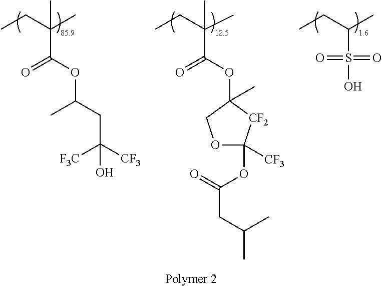

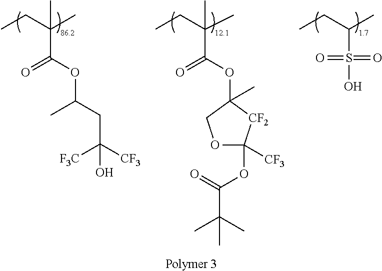

TABLE 2

| | | | | | | | Weight- | |
|---|---|---|---|---|---|---|---|---|
| | | | | | | | average | |
| | | | | | | | molecular | |
| | Monomer | Monomer | Monomer | Monomer | Monomer | Yield | weight | Dispersity |
| | 1 | 5 | 6 | 7 | 8 | (%) | (Mw) | (Mw/Mn) |
| Polymer 4 | 85 | 12.5 | | | 2.5 | 76.4 | 6,700 | 1.44 |
| Polymer 5 | 85 | | 12.5 | | 2.5 | 75.2 | 6,700 | 1.44 |
| Polymer 6 | 85 | | | 12.5 | 2.5 | 74.1 | 6,800 | 1.44 |

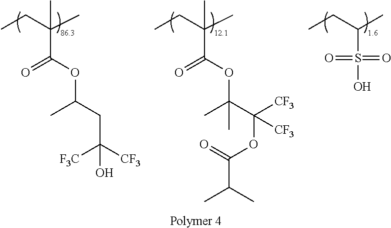

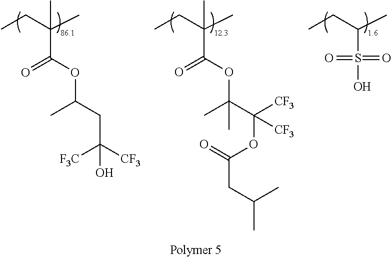

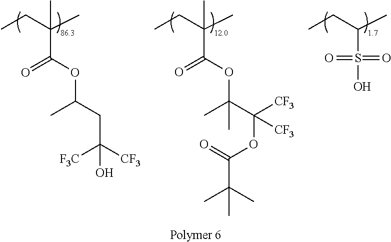

TABLE 3

| | | | | | | Weight- | |
|---|---|---|---|---|---|---|---|
| | | | | | | average | |
| | | | | | | molecular | |
| | Monomer | Monomer | Monomer | Monomer | Yield | weight | Dispersity |
| | 1 | 2 | 9 | 10 | (%) | (Mw) | (Mw/Mn) |
| Polymer 7 | 85 | 12.5 | 2.5 | | 75.0 | 6,700 | 1.44 |
| Polymer 8 | 85 | 12.5 | | 2.5 | 74.2 | 6,900 | 1.44 |

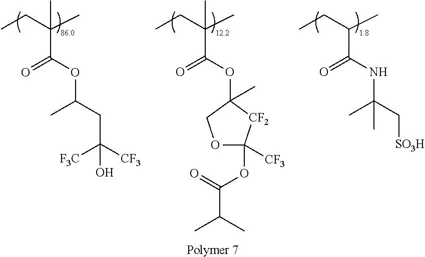

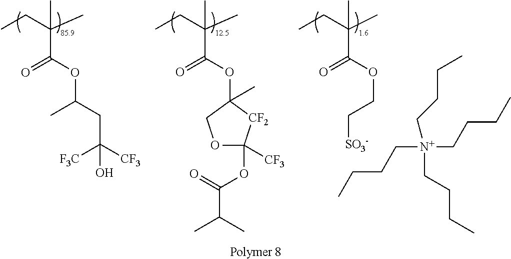

TABLE 4

| | | | | | | | Weight- | |
|---|---|---|---|---|---|---|---|---|
| | | | | | | | average | |
| | | | | | | | molecular | |
| | Monomer | Monomer | Monomer | Monomer | Monomer | Yield | weight | Dispersity |
| | 1 | 2 | 8 | 11 | 12 | (%) | (Mw) | (Mw/Mn) |
| Polymer 9 | 55 | 12.5 | 2.5 | 30 | | 78.9 | 6,800 | 1.44 |
| Polymer 10 | 55 | 12.5 | 2.5 | | 30 | 70.5 | 6,700 | 1.43 |

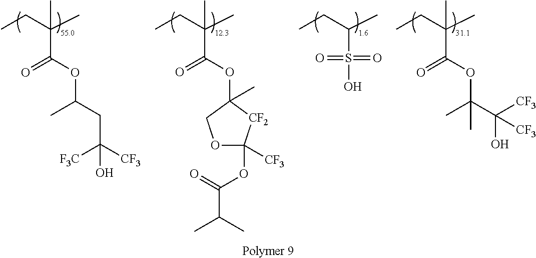

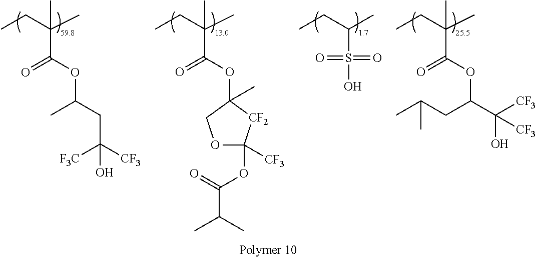

TABLE 5

| | | | | | | | Weight- | |
|---|---|---|---|---|---|---|---|---|
| | | | | | | | average | |
| | | | | | | | molecular | |
| | Monomer | Monomer | Monomer | Monomer | Monomer | Yield | weight | Dispersity |
| | 1 | 2 | 8 | 13 | 14 | (%) | (Mw) | (Mw/Mn) |
| Polymer 11 | 85 | 7.5 | 2.5 | 5 | | 75.5 | 6,700 | 1.44 |
| Polymer 12 | 85 | 7.5 | 2.5 | | 5 | 76.5 | 6,800 | 1.46 |

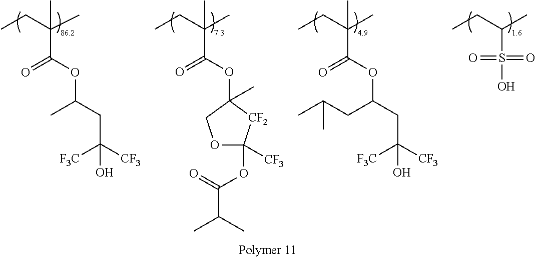

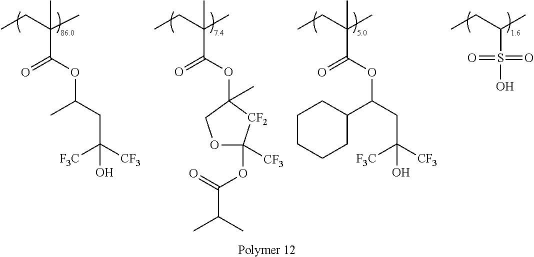

### Polymer Synthesis Example 13

### Copolymerization of Monomer 11 and Monomer 8 (90/10) in the Co-Presence of Base 1

Into a flask under a nitrogen atmosphere, 96.46 g of Monomer 11, 4.03 g of Monomer 8, 1.87 g of Base 1 (se the following formula), 4.18 g of dimethyl 2,2-azobis(isobutyric acid), and 155.56 g of 2-propanol were added to prepare a monomer solution with the solution temperature of 20 to 25° C. Into another flask under a nitrogen atmosphere, 77.78 g of 2-propanol was added, and then heated to 80° C. with stirring; thereafter, into it, the foregoing monomer solution was added drop-wise over 4 hours. After completion of the addition, the resulting polymerization solution was stirred for 2 hours with maintaining the temperature at 80° C., and then cooled to room temperature after completion of aging. The obtained polymerization solution was added with 300 g of 2-propanol, and then washed with 300 g of ultra-highly purified water for 3 times. An organic layer was extracted, concentrated to total mass of 200 g by an evaporator, and then crystallized with 1500 g of hexane. The precipitated copolymer was collected and then washed with 600 g of hexane to separate a white solid substance, which was then dried under vacuum at 50° C. for 20 hours to obtain 79.8 g of an intended polymer (Polymer 13). Composition of the resin was analyzed by ¹H-NMR, showing that composition ratio of Monomer 11, Monomer 8, and the salt between Monomer 8 and Base 1 (see the following formula) be 89.0/9.0/2.0% by mol. A weight-average molecular weight (Mw) obtained by GPC was 7,100 (Mw/Mn=1.44).

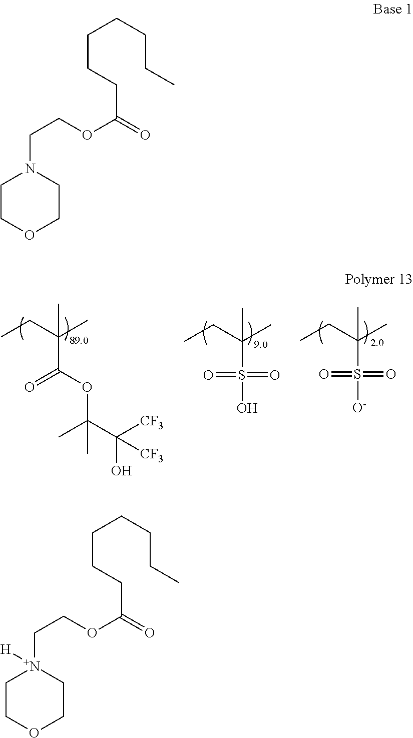

### Comparative Polymer Synthesis Example 1

### Copolymerization of Monomer 1 and Monomer 8 (95/5)

Monomer 1 and Monomer 8 were charged with the mol ratio of 95/5, and then Comparative Polymer 1 was synthesized by a similar manner to those in the synthesis of Polymer 1. Composition of the resin was analyzed by ¹H-NMR, showing that composition ratio of Monomer 1 and Monomer 8 be 96.8/3.2% by mol. A weight-average molecular weight (Mw) obtained by GPC was 7,100 (Mw/Mn=1.44).

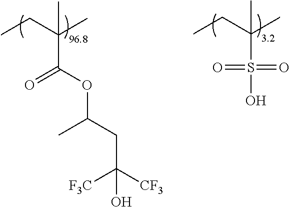

### Comparative Polymer Synthesis Example 2

### Synthesis of Homopolymer of Monomer 11

Into a flask under a nitrogen atmosphere, 100.0 g of Monomer 11, 3.91 g of dimethyl 2,2′-azobis(isobutyric acid), and 100.0 g of 2-propanol were added to prepare a monomer solution with the solution temperature of 20 to 25° C. Into another flask under a nitrogen atmosphere, 50.0 g of 2-propanol was added, and then heated to 80° C. with stirring; thereafter, into it, the foregoing monomer solution was added drop-wise over 4 hours. After completion of the addition, the resulting polymerization solution was stirred for 3 hours with maintaining the temperature at 80° C., and then cooled to room temperature after completion of aging. The obtained polymerization solution was added drop-wise into 2,000 g of water, and then precipitated homopolymer was separated by filtration. The obtained homopolymer was washed with 600 g of hexane/isopropyl ether (9/1) for 4 times to separate a white solid substance, which was then dried under vacuum at 50° C. for 20 hours to obtain 92.8 g of an intended polymer (Comparative Polymer 2). A GPC measurement result of the obtained homopolymer showed a weight-average molecular weight (Mw) of 7,800 based on the polystyrene equivalent and dispersity (Mw/Mn) of 1.6.

### Examples 1 to 18 and Comparative Examples 1 to 3

### Evaluation Examples by Using a Resist Top Coat

Each 1.0 g (as solid) of Polymers 1 to 13 and Comparative Polymers 1 and 2 with a mixing ratio as shown in Table 6 was dissolved into 42.0 g of a mixed solvent of diisopentyl ether/4-methyl-2-pentanol (40/60), and the respective solution was filtrated through a filter made of polypropylene (0.03 μm pore size) to prepare a resist top coat solution (TC-1 to TC-18, Comparative TC-1 to TC-3).

TABLE 6

| | | | | Film | Film | | |
|---|---|---|---|---|---|---|---|
| | | | | Thickness | Thickness | | Receding |
| | Resist | Polymer | Refractive | Change After | Change After | Sliding | Contact |
| | Top Coat | to be used | Index | Rinsing | Development | Angle | Angle |
| | Composition | (mixing ratio) | (at 193 nm) | (nm) | (nm) | (°) | (°) |
| Example 1 | TC-1 | Polymer1(100) | 1.54 | 0 | 0 | 17 | 71 |
| Example 2 | TC-2 | Polymer2(100) | 1.54 | 0 | 0 | 18 | 70 |
| Example 3 | TC-3 | Polymer3(100) | 1.54 | 0 | 0 | 17 | 70 |
| Example 4 | TC-4 | Polymer4(100) | 1.54 | 0 | 0 | 17 | 70 |
| Example 5 | TC-5 | Polymer5(100) | 1.54 | 0 | 0 | 17 | 70 |
| Example 6 | TC-6 | Polymer6(100) | 1.54 | 0 | 0 | 17 | 71 |
| Example 7 | TC-7 | Polymer7(100) | 1.54 | 0 | 0 | 18 | 70 |
| Example 8 | TC-8 | Polymer8(100) | 1.54 | 0 | 0 | 18 | 70 |
| Example 9 | TC-9 | Polymer9(100) | 1.54 | 0 | 0 | 18 | 68 |
| Example 10 | TC-10 | Polymer10(100) | 1.54 | 0 | 0 | 18 | 69 |
| Example 11 | TC-11 | Polymer11(100) | 1.54 | 0 | 0 | 17 | 73 |
| Example 12 | TC-12 | Polymer12(100) | 1.54 | 0 | 0 | 17 | 73 |
| Example 13 | TC-13 | Polymer1(75) | 1.54 | 0 | 0 | 17 | 72 |
| | | Polymer13(25) | | | | | |
| Example 14 | TC-14 | Polymer2(75) | 1.54 | 0 | 0 | 18 | 71 |
| | | Polymer13(25) | | | | | |
| Example 15 | TC-15 | Polymer3(75) | 1.54 | 0 | 0 | 17 | 71 |
| | | Polymer13(25) | | | | | |
| Example 16 | TC-16 | Polymer4(75) | 1.54 | 0 | 0 | 17 | 71 |
| | | Polymer13(25) | | | | | |
| Example 17 | TC-17 | Polymer5(75) | 1.54 | 0 | 0 | 17 | 71 |
| | | Polymer13(25) | | | | | |
| Example 18 | TC-18 | Polymer6(75) | 1.54 | 0 | 0 | 17 | 72 |
| | | Polymer13(25) | | | | | |
| Comparative | Comparative | Comparative | 1.54 | 0 | 0 | 19 | 66 |
| Example 1 | TC-1 | Polymer1(100) | | | | | |
| Comparative | Comparative | Comparative | 1.54 | 0 | 0 | 19 | 69 |
| Example 2 | TC-2 | Polymer2(100) | | | | | |
| Comparative | Comparative | Comparative | 1.54 | 0 | 0 | 19 | 68 |
| Example 3 | TC-3 | Polymer2(75) | | | | | |
| | | Poiymer13(25) | | | | | |

The obtained resist top coat solution was applied on a silicon substrate by spin-coating; and after it was baked at 100° C. for 60 seconds, a resist top coat having 50 nm thickness was obtained. Thereafter, by using the wafer coated with the top coat, measurements were done as to (1) refractive index (at 193 nm wavelength) by a spectro-ellipsometry (manufactured by J. A. Woollam Co., Inc.), (2) film thickness change after rinsing with purified water (for 5 minutes), (3) film thickness change after development by 2.38% by mass of an aqueous tetramethyl ammonium hydroxide (TMAH), and (4) sliding angle and receding contact angle by using the slant contact angle measurement instrument Drop Master 500 (manufactured by Kyowa Interface Science Co., Ltd.) (Examples 1 to 18 and Comparative Examples 1 to 3). The results are shown in Table 6.

From Table 6, it can be seen that the resist top coat compositions (TC-1 to TC-12) using polymer (P1-1) and polymer (P1-2) as the sole polymer have higher receding contact angles than Comparative Polymer 1, indicating that the repeating units represented by the general formulae (1b-1) and (1b-2) are effective to improve water repellent properties (Examples 1 to 12). Further, in the case that polymer (P1-1) or polymer (P1-2) is used as a blend with polymer (P2) (TC-13 to TC-18), the receding contact angles are almost as same as those of the singly used polymer (P1-1) or polymer (P1-2), indicating that the both polymers are separated into layers so that polymer (P1-1) or polymer (P1-2) is present over the polymer (P2) layer (Examples 13 to 18). Generally, water can move more easily on a top coat with lower sliding angle, and lesser water droplets tend to remain on the film with higher receding contact angle even by a high speed scanning exposure; and thus, from Table 6, it can be seen that TC-1 to TC-18, the resist top coat compositions of the present invention, show better performance in the sliding angle and the receding contact angle as compared with Comparative TC-1 to TC-3.

### Examples 19 to 30 and Comparative Examples 4 to 8

### Examples of Resist Evaluation

5 g of the resist polymer, 0.5 g of PAG 1, and 0.1 g of Quencher 1 shown below were dissolved into 100 g of propylene glycol monoethyl ether acetate (PGMEA); and then, the resulting mixture was filtrated through a filter made of polypropylene (0.03 μl of a pore size) to obtain a resist solution.

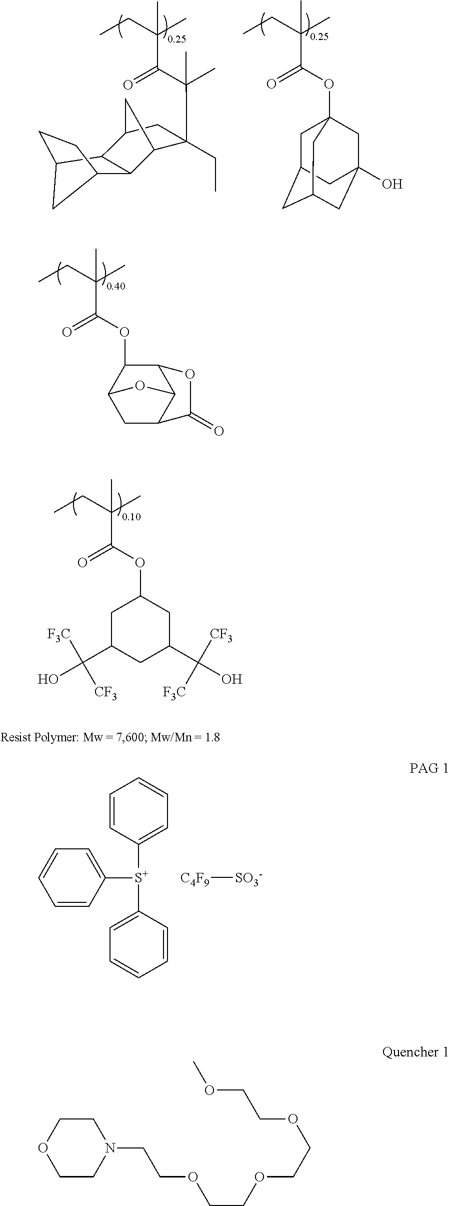

Then, after an anti-reflection film ARC-29A (manufactured by Nissan Chemical Industries, Ltd.) was formed on a silicon substrate (the film thickness of 87 nm), the foregoing resist solution was applied on it and then baked at 105° C. for 60 seconds to obtain a resist film having a 120-nm film thickness. Further on it, the foregoing resist top coat composition was applied and then baked at 100° C. for 60 seconds. To reproduce a quasi-immersion exposure, a film obtained after the exposure was rinsed by purified water for 5 minutes, exposed by using an ArF scanner S307E (manufactured by Nikon Corporation; NA 0.85, σ 0.93/0.62, 20-degree dipole illumination, and 6% half tone phase shift mask), and then rinsed with running purified water for 5 minutes. After a post-exposure bake (PEB) was conducted at 100° C. for 60 seconds, development was conducted by 2.38% by mass of an aqueous TMAH for 60 seconds. Separately, the process of exposure/purified water rinse/PEB/development was also carried out without the top coat. The obtained wafer was cross-cut; and then the form and sensitivity of the 65-nm line-and-space pattern were compared among the samples. Then, 5 μL of a water droplet was dropped on the resist film obtained after the development; and a contact angle between a resist interface and a droplet interface was measured. These results are summarized in Table 7.

TABLE 7

| | | | | Water Contact |
|---|---|---|---|---|
| | Resist | | | Angle After |
| | Top Coat | Sensitivity | 65 nm | Development |
| | Composition | (mJ/cm²) | Pattern Profile | (°) |
| Example 19 | TC-1 | 30 | Rectangular Profile | 60 |
| Example 20 | TC-2 | 29 | Rectangular Profile | 59 |
| Example 21 | TC-3 | 29 | Rectangular Profile | 60 |
| Example 22 | TC-4 | 30 | Rectangular Profile | 61 |
| Example 23 | TC-5 | 30 | Rectangular Profile | 61 |
| Example 24 | TC-6 | 29 | Rectangular Profile | 61 |
| Comparative | Comparative | 29 | Rounding Profile | 61 |
| Example 4 | TC-1 | | | |
| Comparative | Comparative | 28 | Rounding Profile | 68 |
| Example 5 | TC-2 | | | |
| Comparative | Non Top Coat | 30 | T-top Profile | 62 |
| Example 6 | | | | |

When Comparative TC-1 and TC-2 were used, a rounding profile was obtained as the pattern profile (Comparative Examples 4 and 5). When the rinse with purified water was conducted after exposure without forming a top coat, a T-top profile was obtained as the pattern profile (Comparative Example 6). It may be assumed that this was caused by dissolution of a generated acid into water. On the other hand, the top coat compositions of the present invention showed a high receding contact angle, thereby not only leading to a smaller contact angle of the resist after development but also showing a rectangular profile in a resist pattern after development (Examples 19 to 24).

Then, each of the resist top coats used in the foregoing exposure experiments (TC-1 to TC-6 and Comparative TC-1 to TC-2) was micro-filtrated with a filter made of high-density polyethylene having pore size of 0.02 μm. After an anti-reflection film ARC-29A (manufactured by Nissan Chemical Industries, Ltd.) was formed on a 8-inch silicon substrate (film thickness of 87 nm), the resist solution, was applied onto it and then baked at 105° C. for 60 seconds to form a resist film having 120 nm of the film thickness. Onto it the resist top coat was applied and then baked at 100° C. for 60 seconds. A checkered flag exposure, giving alternately a non-exposed part and an exposed part of an open frame having a 20-mm-square area in the entire wafer by using an ArE scanner S307E (manufactured by Nikon Corporation; NA 0.85, σ 0.93, and a Cr-mask), was conducted; and then a post-exposure bake (PEE) was carried out. Thereafter, development was conducted by 2.38% by mass of an aqueous TMAH for 60 seconds. Number of defects in the non-exposed part of the checkered flag was measured by using a defect-testing instrument WinWin-50-1200 (manufactured by Tokyo Seimitsu Co., Ltd.) with a pixel size of 0.125 μm. The defect appeared on a resist surface of the non-exposed part was of a smeared-type so that it can be classified into the blob defect. The results are shown in Table 8. From these results, it can be seen that the resist top coat compositions using polymer (P1-1) and polymer (P1-2) have less defects as compared with the top coat compositions of Comparative Examples.

TABLE 8

| | Resist Top Coat | |
|---|---|---|
| | Composition | Defect Number |
| Example 25 | TC-1 | 16 |
| Example 26 | TC-2 | 20 |
| Example 27 | TC-3 | 25 |
| Example 28 | TC-4 | 17 |
| Example 29 | TC-5 | 19 |
| Example 30 | TC-6 | 28 |
| Comparative | Comparative | 50 |
| Example 7 | TC-1 | |
| Comparative | Comparative | 3,000 |
| Example 8 | TC-2 | |

### Examples 31 to 36 and Comparative Example 9

### Examples of Evaluation of the Electron Beam Exposure

In evaluation of the electron beam drawing, 90 parts by mass of an EB Polymer (shown below) synthesized by radical polymerization, 10 parts by mass of PAG 2 (shown below), and 0.4 parts by mass of Quencher 2 were dissolved in 700 parts by mass of propylene glycol monomethyl ether acetate (PGMEA) and 300 parts by mass of ethyl lactate (EL), and then the resulting mixture was filtrated with a filter having a 0.02 μm pore size to obtain a positive resist composition.

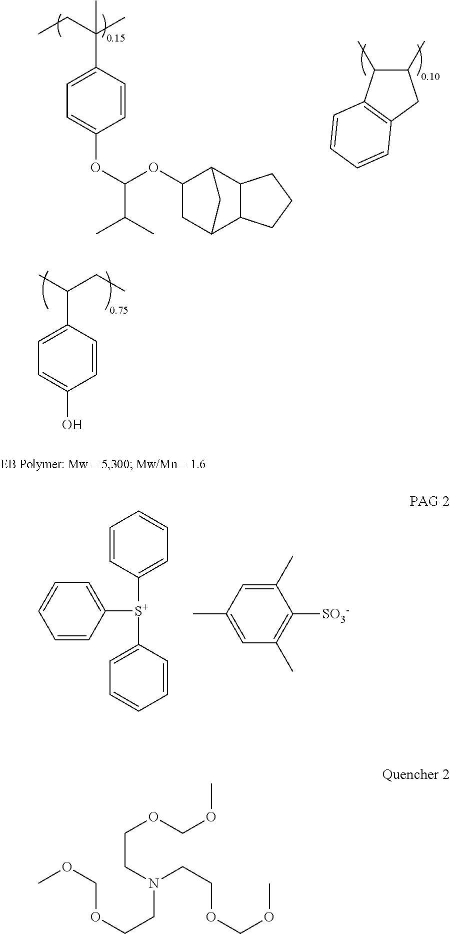

The obtained positive resist composition was applied by spin-coating on a silicon substrate having a 6 inch diameter (150 mm) by using Clean Track Mark 5 (manufactured by Tokyo Electron Limited), and then pre-baked on a hot plate at 110° C. for 60 seconds to obtain a resist film having film thickness of 200 nm. A resist top coat composition was applied on it and then baked at 100° C. for 60 seconds. A vacuum chamber drawing was conducted on this wafer by using HL-800D (manufactured by Hitachi. Ltd.) with HV voltage of 50 keV. It was left in the vacuum chamber for 20 hours, and then an additional drawing was carried out in a different area. Immediately after the drawing, a post-exposure bake (PEB) was carried out on a hot plate at 90° C. for 60 seconds by using Clean Track Mark 5 (manufactured by Tokyo Electron Limited), and then paddle-development was conducted by 2.38% by mass of an aqueous TMAH for 30 seconds to obtain a positive pattern.

Then, by using a CD-SEM (S-7280, manufactured by Hitachi, Ltd.), a dimensional change upon leaving under vacuum was measured as follows. Namely, difference of the line size of a 0.12-μm line-and-space between just before the development and after 20 hours was measured with an exposure dose to resolve the 0.12-μm line-and-space at 1:1; and this difference was taken as the dimensional change. In the dimensional change, a plus sign shows that the resist sensitivity was changed to a higher side by leaving under vacuum, and a minus sign shows that the change was made toward a lower sensitivity. The results are shown in Table 9.

TABLE 9

| | Resist Top Coat | Dimensional |
|---|---|---|
| | Composition | Change (nm) |
| Example 31 | TC-1 | −1 |
| Example 32 | TC-2 | 0 |
| Example 33 | TC-3 | 0 |
| Example 34 | TC-4 | 0 |
| Example 35 | TC-5 | −1 |
| Example 36 | TC-6 | 0 |
| Comparative | Non top coat | −9 |
| Example 9 | | |

In the electron beam exposure, stability upon leaving under vacuum after the exposure was improved by using the resist top coat composition of the present invention (TC-1 to TC-6).

It must be stated here that the present invention is not limited to the foregoing embodiments. The embodiments are examples so that any embodiments composed of substantially the same technical concept as disclosed in the claims of the present invention and expressing a similar effect are included in the technical scope of the present invention.

What is claimed is:

1. A resist top coat composition wherein the composition contains polymer (P1-1) with a weight-average molecular weight of 1,000 to 500,000, having at least repeating units represented by the following general formulae (1a), (1b-1), and (1c): 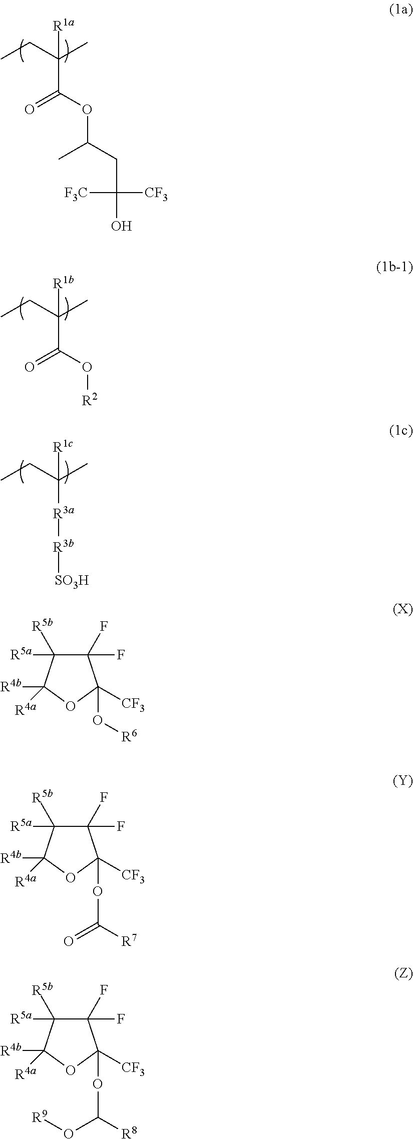
wherein, R^{1a} to R^{1c} represent a hydrogen atom or a methyl group; R² represents a group shown by any of the above general formulae (X), (Y), and (Z), and is connected to a —(C═O)—O— bond in repeating unit (1b-1) via any of R^{4a}, R^{4b}, R^{5a}, and R^{5b} in the general formulae (X), (Y), and (Z), wherein R^{4a}, R^{4b}, R^{5a}, and R^{5b} connected to the —(C═O)—O— bond represent a single bond or a linear, a branched, or a cyclic alkylene group having 1 to 15 carbon atoms; each of R^{4a}, R^{4b}, R^{5a}, and R^{5b} not connected to the —(C═O)—O— bond in repeating unit (1b-1) represents independently any of a hydrogen atom, a hydroxyl group, a halogen atom, and a linear, a branched, and a cyclic monovalent organic group having 1 to 15 carbon atoms, wherein two of R^{4a}, R^{4b}, R^{5a}, and R^{5b} may be bonded with each other to form a cyclic structure; R⁶, R⁷, and R⁹ represent a linear, a branched, or a cyclic alkyl group having 1 to 20 carbon atoms, wherein a part of their hydrogen atoms may be substituted with a halogen atom and a part of a methylene group may be substituted with an oxygen atom or a carbonyl group; R⁸ represents a hydrogen atom, or a linear, a branched, or a cyclic alkyl group having 1 to 20 carbon atoms, wherein a part of their hydrogen atoms may be substituted with a halogen atom and a part of a methylene group may be substituted with an oxygen atom or a carbonyl group. R⁸ and R⁹ may be bonded to form a cyclic structure; R^{3a} represents any of a single bond, —(C═O)—O—, and —(C═O)—NH—; R^{3b} represents a single bond, or a linear, a branched, or a cyclic alkylene group having 1 to 15 carbon atoms; in polymer (P1-1), if total mol of a monomer corresponding to each of the general formulae (1a), (1b-1), and (1c) is made U11, U12, and U13 and total mol of monomers corresponding to entire repeating units contained in polymer (P1-1) is made U1, they are in the following relationships:
0<U11/U1<1,
0<U12/U1<1,
0<U13/U1<1, and
0<(U11+U12+U13)/U1≦1.

2. The resist top coat composition according to claim 1, wherein R^{3a} and R^{3b} in the general formula (1c) are a single bond.

3. A resist top coat composition wherein the composition contains polymer (P1-2) with a weight-average molecular weight of 1,000 to 500,000, having at least repeating units represented by the following general formulae (1a)′, (1b-2), and (1c)′: 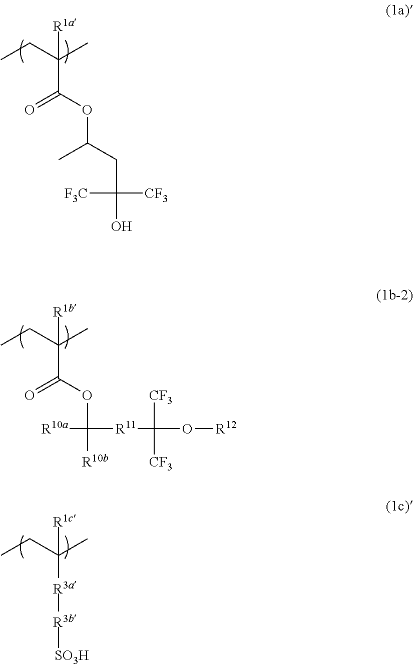
wherein, R^{1a′} to R^{1c′} represent a hydrogen atom or a methyl group; R^{10a} and R^{10b} represent a hydrogen atom, or a linear, a branched, or a cyclic monovalent hydrocarbon group having 1 to 15 carbon atoms, wherein R^{10a} and R^{10b} may be bonded with each other to form a non-aromatic ring having 3 to 8 carbon atoms; R¹¹ represents a single bond or a methylene group; R¹² represents any of a linear, a branched, or a cyclic monovalent hydrocarbon group or a fluorinated monovalent hydrocarbon group having 1 to 15 carbon atoms, and an acid labile group, wherein, in the case of a monovalent hydrocarbon group, a constituting —CH₂— group may be substituted with —O— or —C(═O)—; R^{3a′} represents any of a single bond, —(C═O)—O—, and —(C═O)—NH—; R^{3b′} represents a single bond, or a linear, a branched, or a cyclic alkylene group having 1 to 15 carbon atoms; in polymer (P1-2), if total mol of a monomer corresponding to each of the general formulae (1a)′, (1b-2), and (1c)′ is made U11′, U12′, and U13′ and total mol of monomers corresponding to entire repeating units contained in polymer (P1-2) is made U1′, they are in the following relationships:
0<U11′/U1′<1,
0<U12′/U1′<1,
0<U13′/U1′<1, and
0<(U11′+U12′+U13′)/U1′≦1.

4. The resist top coat composition according to claim 3, wherein R^{3a′} and R^{3b′} in the general formula (1c)′ are a single bond.

5. The resist top coat composition according to claim 1, wherein the resist top coat composition further contains a solvent.

6. The resist top coat composition according to claim 2, wherein the resist top coat composition further contains a solvent.

7. The resist top coat composition according to claim 3, wherein the resist top coat composition further contains a solvent.

8. The resist top coat composition according to claim 4, wherein the resist top coat composition further contains a solvent.

9. The resist top coat composition according to claim 5, wherein the solvent is an ether compound having 8 to 12 carbon atoms.

10. The resist top coat composition according to claim 6, wherein the solvent is an ether compound having 8 to 12 carbon atoms.

11. The resist top coat composition according to claim 7, wherein the solvent is an ether compound having 8 to 12 carbon atoms.

12. The resist top coat composition according to claim 8, wherein the solvent is an ether compound having 8 to 12 carbon atoms.

13. The resist top coat composition according to claim 5, wherein the solvent is one or a combination of two or more of di-n-butyl ether, di-isobutyl ether, di-isopentyl ether, di-n-pentyl ether, methyl cyclopentyl ether, methyl cyclohexyl ether, di-sec-butyl ether, di-sec-pentyl ether, di-t-amyl ether, and di-n-hexyl ether.

14. The resist top coat composition according to claim 12, wherein the solvent is one or a combination of two or more of di-n-butyl ether, di-isobutyl ether, di-isopentyl ether, di-n-pentyl ether, methyl cyclopentyl ether, methyl cyclohexyl ether, di-sec-butyl ether, di-sec-pentyl ether, di-t-amyl ether, and di-n-hexyl ether.

15. The resist top coat composition according to claim 9, wherein the solvent contains, in addition to the ether compounds, one alcohol or a mixture of two or more of alcohols selected from any of 1-butyl alcohol, 2-butyl alcohol, isobutyl alcohol, tert-butyl alcohol, 1-pentanol, 2-pentanol, 3-pentanol, tert-amyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-diethyl-2-butanol, 3,3-dimethyl-1-butanol, 3,3-dimethyl-2-butanol, 2-diethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, and cyclohexanol.

16. The resist top coat composition according to claim 14, wherein the solvent contains, in addition to the ether compounds, one alcohol or a mixture of two or more of alcohols selected from any of 1-butyl alcohol, 2-butyl alcohol, isobutyl alcohol, tert-butyl alcohol, pentanol, 2-pentanol, 3-pentanol, tert-amyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-diethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, and cyclohexanol.

17. A patterning process wherein the process includes at least (1) a step of forming a photoresist film over a substrate, (2) a step of forming a resist top coat on the photoresist film by using the resist top coat composition according to claim 1, (3) a step of exposure, and (4) a step of developing by using a developer.

18. A patterning process wherein the process includes at least (1) a step of forming a photoresist film over a substrate, (2) a step of forming a resist top coat on the photoresist film by using the resist top coat composition according to claim 16, (3) a step of exposure, and (4) a step of developing by using a developer.

19. The patterning process according to claim 17, wherein the step of exposure (3) is conducted by an immersion lithography wherein the exposure is conducted by using a high energy beam via a photo mask while inserting a liquid between a projection lens and the substrate.

20. The patterning process according to claim 18, wherein the step of exposure (3) is conducted by an immersion lithography wherein the exposure is conducted by using a high energy beam via a photo mask while inserting a liquid between a projection lens and the substrate.

21. The patterning process according to claim 19, wherein the liquid inserted between the projection lens and the substrate in the step of exposure (3) is water.

22. The patterning process according to claim 20, wherein the liquid inserted between the projection lens and the substrate in the step of exposure (3) is water.

23. The patterning process according to claim 17, wherein a high energy beam having a wavelength in the range between 180 and 250 nm is used as an exposure light source in the step of exposure (3).

24. The patterning process according to claim 22, wherein a high energy beam having a wavelength in the range between 180 and 250 nm is used as an exposure light source in the step of exposure (3).

25. The patterning process according to claim 17, wherein delamination of the resist top coat on the photoresist film is conducted at the same time as development by using an alkaline developer to form a resist pattern on the photoresist film in the step of development (4).

26. The patterning process according to claim 24, wherein delamination of the resist top coat on the photoresist film is conducted at the same time as development by using an alkaline developer to form a resist pattern on the photoresist film in the step of development (4).

27. A patterning process by lithography comprising steps of; forming a resist top coat by using a resist top coat composition on a photoresist layer formed over a mask blanks; conducting an exposure by an electron beam under vacuum; and developing, wherein the resist top coat composition according to claim 1 is used as the resist top coat composition.

28. A patterning process by lithography comprising steps of; forming a resist top coat by using a resist top coat composition on a photoresist layer formed over a mask blanks; conducting an exposure by an electron beam under vacuum; and developing, wherein the resist top coat composition according to claim 16 is used as the resist top coat composition.
